(19) United States
(12) Patent Application Publication
(10) Pub. No.: US 2024/0178258 A1
(43) Pub. Date: May 30, 2024

(54) PHOTOELECTRIC CONVERSION APPARATUS

(71) Applicant: CANON KABUSHIKI KAISHA, Tokyo (JP)

(72) Inventors: HIROSHI SEKINE, Kanagawa (JP); KAZUHIRO MORIMOTO, Kanagawa (JP); KOSEI UEHIRA, Tokyo (JP)

(21) Appl. No.: 18/522,013

(22) Filed: Nov. 28, 2023

(30) Foreign Application Priority Data
Nov. 29, 2022 (JP) 2022-190036
Oct. 30, 2023 (JP) 2023-186022

(51) Int. Cl. H01L 27/146; H01L 23/00

(52) U.S. Cl. CPC H01L 27/14634; H01L 24/08; H01L 24/80; H01L 27/14636; H01L 27/1469; H01L 2224/08145; H01L 2224/80895; H01L 2224/80896

(57) ABSTRACT

A photoelectric conversion apparatus including: a first component including a first substrate (FS) having a first plane and a pixel region in which avalanche photodiodes are arranged, and a first wiring layer provided on a side where the first plane of the FS is provided; and a second component including a second substrate (SS), a quenching device, and a second wiring layer, the SS having a third plane, the second wiring layer being provided on a side where the third plane of the SS is provided. The SS has an insulating region, and the insulating region has a through-electrode provided in a through-region that penetrates through the SS. The quenching device is separated from another element by the insulating region. The first component and the second component are electrically connected to each other in a region that overlaps the pixel region in a plan view.

### BACKGROUND

### Field of the Disclosure

The present disclosure relates to a photoelectric conversion apparatus.

### Description of the Related Art

International Publication No. 2021/256142 discloses a structure in which a through-region and a through-via are formed in a photoelectric conversion apparatus having complementary meta-oxide-semiconductor (CMOS) pixels.

International Publication No. 2021/256142 makes no mention of a photoelectric conversion apparatus having single-photon avalanche diode (SPAD) pixels and does not indicate a suitable arrangement of a through-region and a through-via in a photoelectric conversion apparatus having SPAD pixels.

### SUMMARY

A first aspect of the present disclosure is a photoelectric conversion apparatus including: a first component including a first substrate and a first wiring layer, the first substrate having a first plane and a second plane facing the first plane and having a pixel region in which a plurality of avalanche photodiodes are arranged, the first wiring layer being provided on a side where the first plane of the first substrate is provided; and a second component including a second substrate, a quenching device, and a second wiring layer, the second substrate having a third plane and a fourth plane facing the third plane, the second wiring layer being provided on a side where the third plane of the second substrate is provided. The second substrate has an insulating region, and the insulating region has a through-electrode provided in a through-region that penetrates through the second substrate. The quenching device is separated from another element by the insulating region. The first component and the second component are electrically connected to each other in a region that overlaps the pixel region in a plan view.

Further features of the present disclosure will become apparent from the following description of exemplary embodiments (with reference to the attached drawings).

### BRIEF DESCRIPTION OF THE DRAWINGS

FIG. 1 is a diagram illustrating the configuration of a photoelectric conversion apparatus according to one or more aspects of the present disclosure.

FIG. 2 illustrates an example of the arrangement of a sensor substrate of the photoelectric conversion apparatus according to one or more aspects of the present disclosure.

FIG. 3 illustrates an example of the arrangement of a circuit substrate of the photoelectric conversion apparatus according to one or more aspects of the present disclosure.

FIG. 4 is a block diagram including an equivalent circuit of a photoelectric conversion element of the photoelectric conversion apparatus according to one or more aspects of the present disclosure.

FIGS. 5A to 5C are diagrams illustrating relationships between an operation of an avalanche photodiode (APD) and output signals in the photoelectric conversion apparatus according to one or more aspects of the present disclosure.

FIGS. 6A and 6B are plan views of a photoelectric conversion apparatus according to one or more aspects of the present disclosure.

FIGS. 7A and 7B are cross-section diagrams of the photoelectric conversion apparatus according to one or more aspects of the present disclosure.

FIG. 8 is a plan view of a quenching device section of the photoelectric conversion apparatus according to one or more aspects of the present disclosure.

FIGS. 9A and 9B are cross-sectional views of the quenching device section of the photoelectric conversion apparatus according to one or more aspects of the present disclosure.

FIG. 10 is a flow diagram illustrating a manufacturing method of the photoelectric conversion apparatus according to one or more aspects of the present disclosure.

FIG. 11 is a modification example of a plan view of the photoelectric conversion apparatus according to one or more aspects of the present disclosure.

FIGS. 12A and 12B are plan views of the photoelectric conversion apparatus according to one or more aspects of the present disclosure.

FIG. 13 is a modification example of a plan view of the quenching device section of the photoelectric conversion apparatus according to one or more aspects of the present disclosure.

FIG. 14 is an enlarged cross-sectional view of the photoelectric conversion apparatus according to one or more aspects of the present disclosure.

FIG. 15 is a modification example of the enlarged cross-sectional view of the photoelectric conversion apparatus according to one or more aspects of the present disclosure.

FIG. 16 is a cross-sectional view of the photoelectric conversion apparatus according to one or more aspects of the present disclosure.

FIG. 17 is a cross-sectional view of the photoelectric conversion apparatus according to one or more aspects of the present disclosure.

FIG. 18 is a cross-sectional view of the photoelectric conversion apparatus according to one or more aspects of the present disclosure.

FIGS. 19A and 19B are cross-sectional views of a quenching device of a photoelectric conversion apparatus according to one or more aspects of the present disclosure.

FIG. 20 is a flow diagram illustrating a manufacturing method of the photoelectric conversion apparatus according to one or more aspects of the present disclosure.

FIGS. 21A and 21B are plan views of a photoelectric conversion apparatus according to one or more aspects of the present disclosure.

FIG. 22 is a cross-sectional view of the photoelectric conversion apparatus according to one or more aspects of the present disclosure.

FIGS. 23A and 23B are plan views of a photoelectric conversion apparatus according to one or more aspects of the present disclosure.

FIGS. 24A and 24B are cross-sectional views of the photoelectric conversion apparatus according to one or more aspects of the present disclosure.

FIGS. 25A and 25B are modification examples of the cross-sectional views of the photoelectric conversion apparatus according to one or more aspects of the present disclosure.

FIGS. 26A and 26B are plan views of a photoelectric conversion apparatus according to one or more aspects of the present disclosure.

FIGS. 27A and 27B are cross-sectional views of the photoelectric conversion apparatus according to one or more aspects of the present disclosure.

FIGS. 28A and 28B are modification examples of the cross-sectional views of the photoelectric conversion apparatus according to one or more aspects of the present disclosure.

FIG. 29 is a diagram illustrating the configuration of a photoelectric conversion apparatus according to one or more aspects of the present disclosure.

FIG. 30 illustrates an example of the arrangement of a sensor substrate of the photoelectric conversion apparatus according to one or more aspects of the present disclosure.

FIG. 31 illustrates an example of the arrangement of a circuit substrate of the photoelectric conversion apparatus according to one or more aspects of the present disclosure.

FIG. 32 illustrates an example of the arrangement of the circuit substrate of the photoelectric conversion apparatus according to one or more aspects of the present disclosure.

FIG. 33 is a block diagram including an equivalent circuit of a photoelectric conversion element of the photoelectric conversion apparatus according to one or more aspects of the present disclosure.

FIGS. 34A, 34B, and 34C are plan views of the photoelectric conversion apparatus according to one or more aspects of the present disclosure.

FIG. 35 is a cross-sectional view of the photoelectric conversion apparatus according to one or more aspects of the present disclosure.

FIG. 36 is a flow diagram illustrating a manufacturing method of the photoelectric conversion apparatus according to one or more aspects of the present disclosure.

FIG. 37 is a cross-sectional view of a photoelectric conversion apparatus according to one or more aspects of the present disclosure.

FIG. 38 is a flow diagram illustrating a manufacturing method of the photoelectric conversion apparatus according to one or more aspects of the present disclosure.

FIG. 39 is a cross-sectional view of a photoelectric conversion apparatus according to one or more aspects of the present disclosure.

FIG. 40 is a flow diagram illustrating a manufacturing method of the photoelectric conversion apparatus according to one or more aspects of the present disclosure.

FIG. 41 is a functional block diagram of a photoelectric conversion system according to one or more aspects of the present disclosure.

FIGS. 42A and 42B are functional block diagrams of a photoelectric conversion system according to one or more aspects of the present disclosure.

FIG. 43 is a functional block diagram of a photoelectric conversion system according to one or more aspects of the present disclosure.

FIG. 44 is a functional block diagram of a photoelectric conversion system according to one or more aspects of the present disclosure.

FIGS. 45A and 45B are functional block diagrams of a photoelectric conversion system according to one or more aspects of the present disclosure.

### DESCRIPTION OF THE EMBODIMENTS

Embodiments to be described below are concretizations of the technical idea of the present disclosure and are not intended to limit the scope of the present disclosure. The sizes of and the positional relationship between members illustrated in the individual drawings may be exaggerated for purposes of clear description. In the following description, the identical configurations may be denoted by the same reference signs, and description thereof may be omitted.

In the following, the embodiments of the present disclosure will be described in detail on the basis of the drawings. Note that, in the following description, terms representing specific directions and positions (for example, “up”, “down”, “right”, “left”, and other terms including these terms) are used as needed. These terms are used to facilitate understanding of the embodiments with reference to the drawings, and the meanings of these terms are not intended to limit the technical scope of the present disclosure.

Herein, “a plan view” refers to viewing from a direction perpendicular to a light incident surface of a semiconductor layer. Moreover, “a cross-sectional view” refers to viewing a plane along a direction perpendicular to the light incident surface of the semiconductor layer. Note that in a case where the light incident surface of the semiconductor layer is microscopically rough, a plan view is defined with reference to the light incident surface of the semiconductor layer that is viewed macroscopically.

In the following description, the anode of an avalanche photodiode (APD) is set to a fixed electric potential, and a signal is extracted from the cathode side. Thus, a first-conductivity-type semiconductor region where charges having the same polarity as that of signal charges are treated as majority carriers is an N-type semiconductor region. A second-conductivity-type semiconductor region where charges having a different polarity from that of the signal charges are treated as majority carriers is a P-type semiconductor region.

Note that the present disclosure is achieved even in a case where the cathode of the APD is set to a fixed electric potential and where a signal is extracted from the anode side. In this case, the first-conductivity-type semiconductor region where charges having the same polarity as that of signal charges are treated as majority carriers is a P-type semiconductor region, and the second-conductivity-type semiconductor region where charges having a different polarity from that of the signal charges are treated as majority carriers is an N-type semiconductor region. In the following, a case will be described where one of the nodes of an APD is set to a fixed electric potential; however, the potentials of both of the nodes may vary.

Herein, in a case where the term “impurity concentration” is simply used, the term refers to a net impurity concentration obtained by subtracting an amount compensated by impurities of the reverse conductivity type. That is, “impurity concentration” refers to NET doping concentration. A region where P-type doping concentration is higher than N-type doping concentration is a P-type semiconductor region. In contrast, a region where N-type doping concentration is higher than P-type doping concentration is an N-type semiconductor region.

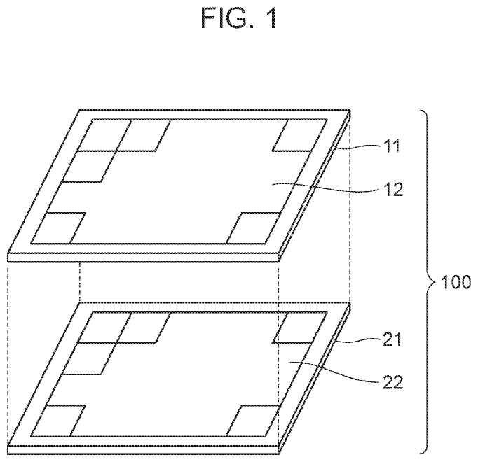

The configuration common to embodiments of photoelectric conversion apparatuses according to the present disclosure and their driving methods will be described using FIG. 1 to FIG. 5C.

FIG. 1 is a diagram illustrating the configuration of a photoelectric conversion apparatus 100 of a multilayer type according to an embodiment of the present disclosure.

The photoelectric conversion apparatus 100 includes two substrates which are stacked one on top of the other and are electrically connected to each other. The two substrates are a sensor substrate 11 and a circuit substrate 21. The sensor substrate 11 has a first semiconductor layer and a first wiring layer. The first semiconductor layer has photoelectric conversion elements 102, which will be described later. The circuit substrate 21 has a second semiconductor layer and a second wiring layer. The second semiconductor layer has, for example, signal processing units 103, which will be described later. In the photoelectric conversion apparatus described in each embodiment, the surface of a first semiconductor layer 300 that is in contact with a first wiring layer 301 is called the front surface (a first plane) of the first semiconductor layer 300, and the surface of the first semiconductor layer 300 on the opposite side from the first plane is called the rear surface (a second plane) of the first semiconductor layer 300.

Similarly, the surface of a second semiconductor layer 400 that is in contact with a second wiring layer 401 is called the front surface (a third plane) of the second semiconductor layer 400, and the surface of the second semiconductor layer 400 on the opposite side from the third plane is called the rear surface (a fourth plane) of the second semiconductor layer 400. In the following, the sensor substrate 11 and the circuit substrate 21 will be described as chips obtained by dicing; however, the sensor substrate 11 and the circuit substrate 21 are not limited to such chips. For example, each substrate may be a wafer. The individual substrates may be stacked one on top of the other in a wafer state and then be subjected to dicing. Alternatively, the individual substrates may be divided into chips, and chips may be staked one on top of the other and joined to each other.

A pixel region 12 is arranged on the sensor substrate 11, and a circuit region 22, which processes signals detected by the pixel region 12, is arranged on the circuit substrate 21.

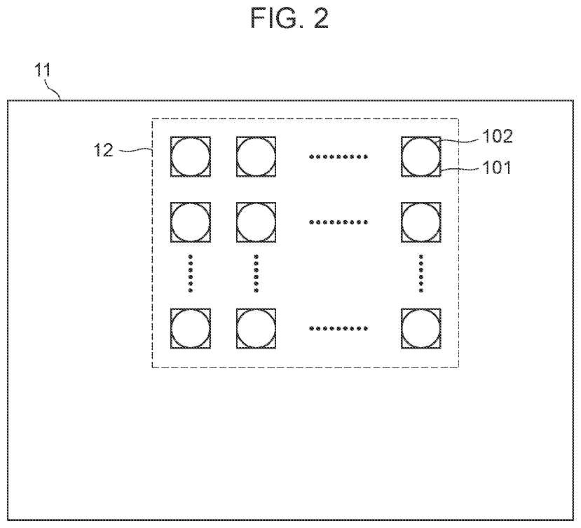

FIG. 2 is a diagram illustrating an example of the arrangement of the sensor substrate 11. The pixel region 12 is formed by arranging, in a two-dimensional array in a plan view, pixels 101 having photoelectric conversion elements 102 including APDs.

Typically, the pixels 101 are pixels for forming an image; however, the pixels 101 do not have to form an image when used for time of flight (TOF). That is, the pixels 101 may also be used to measure the time of arrival of light and the amount of light.

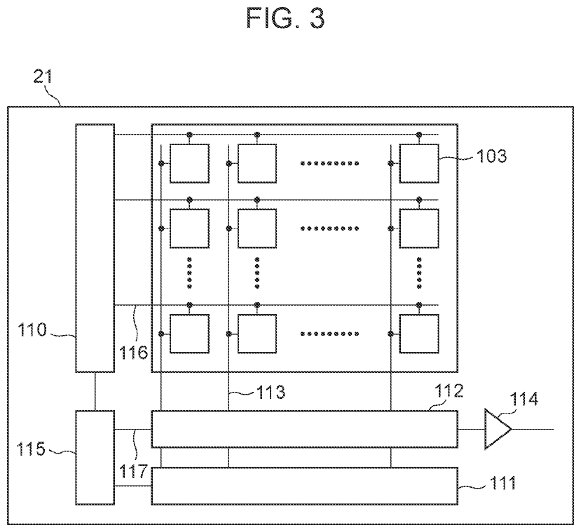

FIG. 3 is a diagram of the configuration of the circuit substrate 21. The circuit substrate 21 has signal processing units 103, a read-out circuit 112 (a column circuit 112), a control pulse generation unit 115, a horizontal scanning circuit unit 111, signal lines 113, and a vertical scanning circuit unit 110. The signal processing units 103 process electric charge obtained by photoelectric conversion performed by the photoelectric conversion elements 102 in FIG. 2.

The photoelectric conversion elements 102 in FIG. 2 are electrically connected to the signal processing units 103 in FIG. 3 via connection wiring lines provided on a pixel basis.

The vertical scanning circuit unit 110 receives a control pulse supplied from the control pulse generation unit 115 and supplies the control pulse to each pixel. In the vertical scanning circuit unit 110, a logic circuit such as a shift register or an address decoder is used.

In each pixel 101, a signal output from the photoelectric conversion element 102 is processed by the signal processing unit 103. The signal processing unit 103 is provided with a counter, a memory, and the like, and the memory holds a digital value.

To read out signals from the memories of the individual pixels in which digital signals are held, the horizontal scanning circuit unit 111 inputs, into the signal processing units 103, a control pulse for sequentially selecting a column.

Regarding a selected column, a signal is output from the signal processing unit 103 of the pixel selected by the vertical scanning circuit unit 110 to a corresponding one of the signal lines 113.

The signal output to the signal line 113 is output through an output circuit 114 to a recording unit or a signal processing unit outside the photoelectric conversion apparatus 100.

In FIG. 2, the photoelectric conversion elements 102 in the pixel region 12 may be arranged in a one-dimensional shape. In addition, it is also possible to obtain the effects of the present disclosure even if there is only one pixel, and the case of a single pixel is also included in the present disclosure. Each of the photoelectric conversion elements 102 does not always need to have the function of the signal processing unit 103. For example, one signal processing unit 103 may be shared by a plurality of photoelectric conversion elements 102, and signal processing may be sequentially performed for the plurality of photoelectric conversion elements 102.

As illustrated in FIGS. 2 and 3, the signal processing units 103 are arranged in a region that overlaps the pixel region 12 in a plan view. The vertical scanning circuit unit 110, the horizontal scanning circuit unit 111, the column circuit 112, the output circuit 114, and the control pulse generation unit 115 are arranged so as to overlap a region between the ends of the sensor substrate 11 and the ends of the pixel region 12 in a plan view. In other words, the sensor substrate 11 includes the pixel region 12 and a non-pixel region surrounding the pixel region 12. The vertical scanning circuit unit 110, the horizontal scanning circuit unit 111, the column circuit 112, the output circuit 114, and the control pulse generation unit 115 are arranged in a region that overlaps the non-pixel region in a plan view.

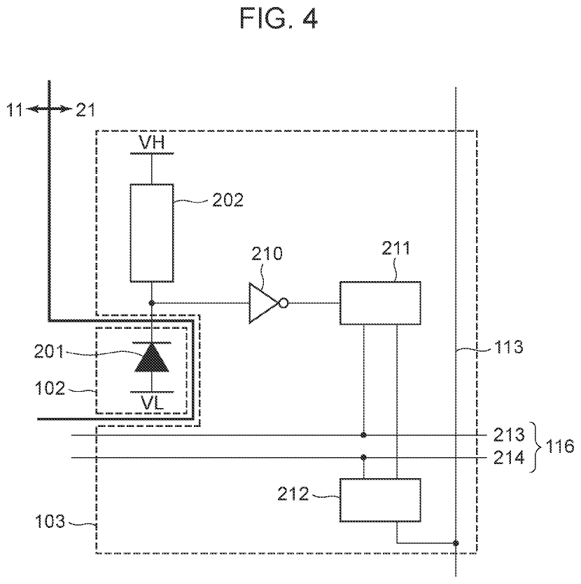

FIG. 4 is an example of a block diagram including equivalent circuits of FIGS. 2 and 3.

In FIG. 4, the sensor substrate 11 is provided with the photoelectric conversion element 102 including an APD 201, and the circuit substrate 21 is provided with the other members.

The APD 201 generates, through photoelectric conversion, a charge pair corresponding to incident light. A voltage VL (a first voltage) is supplied to the anode of the APD 201. A voltage VH (a second voltage) higher than the voltage VL, which is supplied to the anode, is supplied to the cathode of the APD 201. A reverse bias voltage (a voltage greater than or equal to a breakdown voltage) is supplied to the anode and the cathode such that the APD 201 performs an avalanche multiplication operation. With such a voltage applied, electric charge generated by incident light causes an avalanche multiplication, so that an avalanche current is generated.

Note that, in a case where a reverse bias voltage is supplied, there are Geiger and Linear modes.

In Geiger mode, an APD is operated with a potential difference between the anode and the cathode that is greater than the breakdown voltage. In Linear mode, an APD is operated with a potential difference between the anode and the cathode that is near or less than or equal to the breakdown voltage.

An APD operated in Geiger mode is called a single-photon avalanche diode (SPAD). For example, the voltage VL (the first voltage) is −30 V, and the voltage VH (the second voltage) is 1 V. The APD 201 may be operated in Linear mode or in Geiger mode.

A quenching device 202 is connected to a power supply for supplying the voltage VH and the APD 201. The quenching device 202 functions as a load circuit (a quenching circuit) at the time of signal multiplication due to avalanche multiplication, reduces a voltage to be supplied to the APD 201, and helps to prevent avalanche multiplication (a quenching operation). In addition, the quenching device 202 functions to return the voltage to be supplied to the APD 201 back to the voltage VH by causing a current corresponding to a voltage drop caused by the quenching operation to flow (a recharge operation).

The signal processing unit 103 includes a waveform shaping unit 210, a counter circuit 211, and a selection circuit 212. Herein, it is sufficient that the signal processing unit 103 include any one out of the waveform shaping unit 210, the counter circuit 211, and the selection circuit 212. The signal processing unit 103 can also be called a pixel circuit that processes a signal output from the photoelectric conversion element. The waveform shaping unit 210 shapes a change in the electric potential of the cathode of the APD 201 obtained at the time of photon detection, and outputs a pulse signal. As the waveform shaping unit 210, for example, an inverter circuit is used. In FIG. 4, an example is illustrated in which one inverter is used as the waveform shaping unit 210; however, a circuit in which a plurality of inverters are connected in series may be used or another circuit achieving a waveform shaping effect may be used.

The counter circuit 211 counts the number of pulse signals output from the waveform shaping unit 210 and holds a count value. When a control pulse pRES is supplied via a drive line 213, the signal held by the counter circuit 211 is reset.

A control pulse pSEL is supplied to the selection circuit 212 from the vertical scanning circuit unit 110 illustrated in FIG. 3 via a drive line 214 illustrated in FIG. 4 (not illustrated in FIG. 3), and electrical connection and disconnection between the counter circuit 211 and the signal line 113 are switched. The selection circuit 212 includes, for example, a buffer circuit for outputting a signal.

Electrical connection may be switched by arranging a switch such as a transistor between the quenching device 202 and the APD 201 or between the photoelectric conversion element 102 and the signal processing unit 103. Similarly, supply of the voltage VH or voltage VL to be supplied to the photoelectric conversion element 102 may be electrically switched using a switch such as a transistor.

In the present embodiment, a configuration using the counter circuit 211 is illustrated. However, the photoelectric conversion apparatus 100 may acquire a pulse detection timing using a time-to-digital converter (hereinafter referred to as TDC) and a memory instead of the counter circuit 211. In this case, the timing of occurrence of a pulse signal output from the waveform shaping unit 210 is converted into a digital signal by the TDC. To measure a timing of a pulse signal, a control pulse pREF (a reference signal) is supplied to the TDC from the vertical scanning circuit unit 110 illustrated in FIG. 3 via a drive line. The TDC acquires, as a digital signal, a signal obtained when the timing of input of a signal output from each pixel via the waveform shaping unit 210 is treated as a relative time with respect to the control pulse pREF.

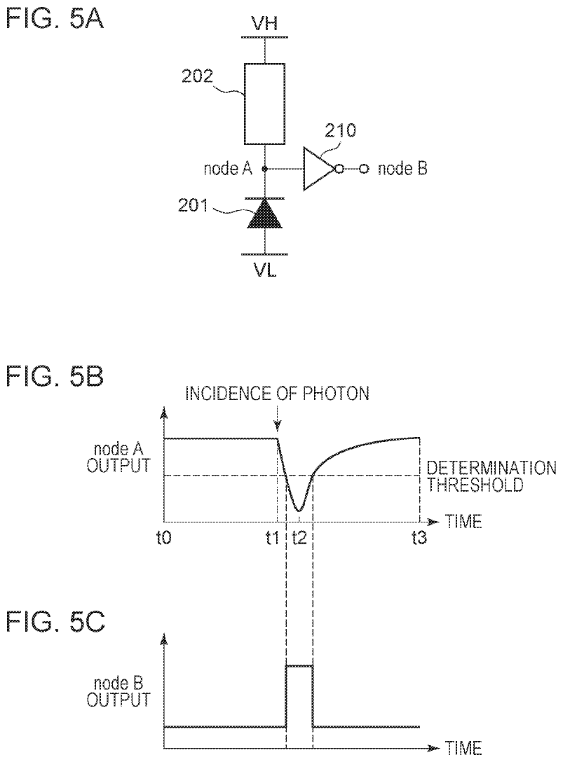

FIGS. 5A to 5C are diagrams schematically illustrating relationships between an operation of the APD and output signals.

FIG. 5A is a diagram illustrating the APD 201, the quenching device 202, and the waveform shaping unit 210 extracted from FIG. 4. In this case, the input side of the waveform shaping unit 210 is a node A, and the output side of the waveform shaping unit 210 is a node B. FIG. 5B illustrates changes in waveform at the node A in FIG. 5A, and FIG. 5C illustrates changes in waveform at the node B in FIG. 5A.

During the period from a time to t0 a time t1, a potential difference of (VH−VL) is applied to the APD 201 in FIG. 5A. When a photon is incident on the APD 201 at the time t1, avalanche multiplication occurs in the APD 201, an avalanche multiplication current flows through the quenching device 202, and the voltage at the node A drops. When the amount of voltage drop further increases, and the potential difference applied to the APD 201 decreases, the avalanche multiplication in the APD 201 stops as indicated at a time t2, and the voltage level at the node A does not fall below a certain value. Thereafter, a current for compensating the amount of voltage drop flows through the node A from the voltage VL during the period from the time t2 to a time t3, and the potential level at the node A becomes stable at its original potential level at the time t3. In this case, part of the output waveform exceeding a certain threshold at the node A is shaped by the waveform shaping unit 210 and is output as a signal from the node B.

Note that the arrangement of the signal lines 113, the column circuit 112, and the output circuit 114 is not limited to the arrangement illustrated in FIG. 3. For example, the signal lines 113 may be arranged so as to extend in the row direction, and the column circuit 112 may be arranged at a position beyond the signal lines 113 and in the direction in which the signal lines 113 extend.

In the following, photoelectric conversion apparatuses according to the individual embodiments will be described. Note that the sensor substrate 11 described above may also be called a first substrate, and the circuit substrate 21 described above may also be called a second substrate. Moreover, the rear surface side of the first semiconductor layer defined above may also be called a light-incident side.

### First Embodiment

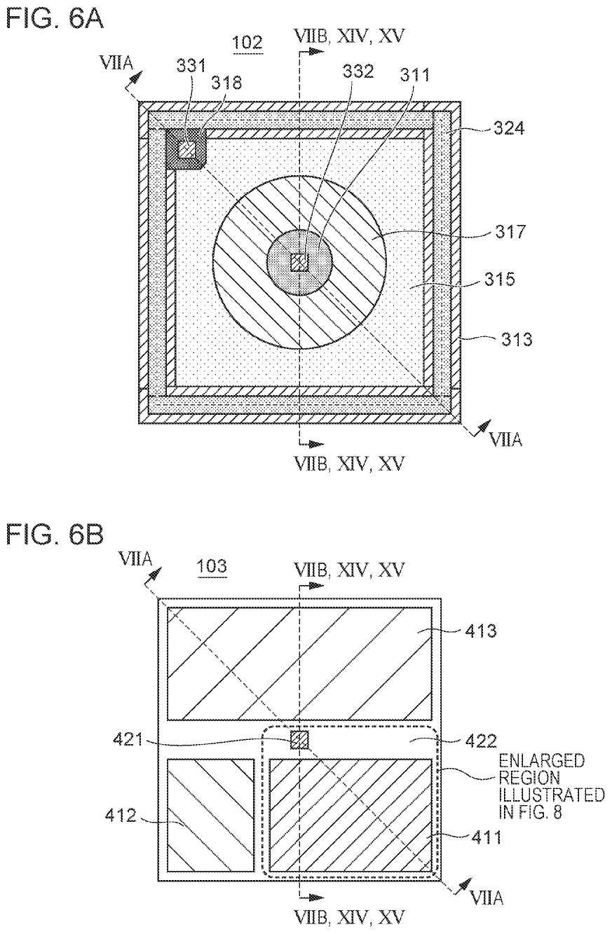

A photoelectric conversion apparatus according to a first embodiment will be described using FIGS. 6A to 18.

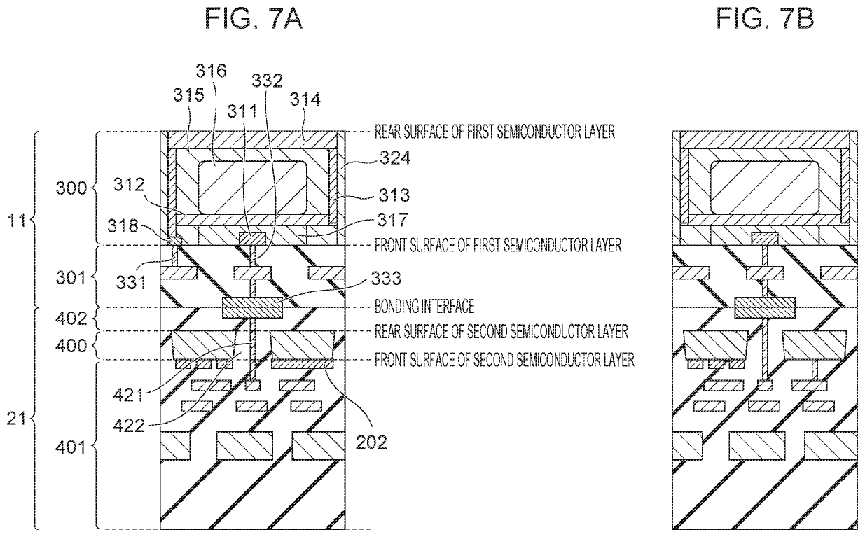

FIG. 6A is a plan schematic diagram of a pixel of the first substrate. FIG. 6A schematically illustrates the structure of the photoelectric conversion element 102. FIG. 6B is a plan schematic diagram of the pixel of the second substrate. FIG. 6B is a block diagram of the signal processing unit 103. FIG. 7A illustrates a cross-section schematic diagram corresponding to a cross section taken along VIIA-VIIA of FIGS. 6A and 6B, and FIG. 7B illustrates a cross-section schematic diagram corresponding to a cross section taken along VIIB-VIIB of FIGS. 6A and 6B.

A first substrate 11 includes a first semiconductor layer 300 and a first wiring layer 301. A second substrate 21 includes a second semiconductor layer 400 and a second wiring layer 401. The second substrate 21 may further include a second-substrate rear-surface interlayer film layer 402. The first substrate 11 and the second substrate 21 are stacked such that the first semiconductor layer 300, the first wiring layer 301, the second-substrate rear-surface interlayer film layer 402, the second semiconductor layer 400, and the second wiring layer 401 are stacked in this order from the rear surface side of the first semiconductor layer. In the following, the configurations and functions of the individual layers and the connection relationships between the layers will be described.

First, the structure and function of each photoelectric conversion element 102 of the first semiconductor layer 300 will be described. The photoelectric conversion element 102 includes N-type semiconductor regions: a first semiconductor region 311, a fifth semiconductor region 315, a sixth semiconductor region 316, and a seventh semiconductor region 317. Moreover, the photoelectric conversion element 102 includes P-type semiconductor regions: a second semiconductor region 312, a third semiconductor region 313, a fourth semiconductor region 314, and an eighth semiconductor region 318.

In the present embodiment, in the cross sections illustrated in FIGS. 7A and 7B, the N-type first semiconductor region 311 is formed near the front surface of the first semiconductor layer (at a first depth), and the N-type seventh semiconductor region 317 is formed in the vicinity of the N-type first semiconductor region 311. The P-type second semiconductor region 312 is formed at a position (a second depth) that overlaps the first semiconductor region 311 and the seventh semiconductor region 317 in a plan view. The N-type sixth semiconductor region 316 is further arranged at a position (a third depth) that overlaps the second semiconductor region 312 in a plan view, and the P-type third semiconductor region 313 is formed in the vicinity of the N-type sixth semiconductor region 316. Furthermore, the P-type fourth semiconductor region 314 is formed on the rear surface side of the first semiconductor layer.

The first semiconductor region 311 has a higher N-type impurity concentration than the seventh semiconductor region 317. A PN junction is formed between the P-type second semiconductor region 312 and the N-type first semiconductor region 311. By making the impurity concentration of the second semiconductor region 312 lower than that of the first semiconductor region 311, the entirety of a region of the second semiconductor region 312 that overlaps the center of the first semiconductor region 311 in a plan view becomes a depletion region. In this case, the potential difference between the first semiconductor region 311 and the second semiconductor region 312 is larger than the potential difference between the second semiconductor region 312 and the seventh semiconductor region 317. Furthermore, this depletion region extends to a portion of the first semiconductor region 311, and a strong electric field is induced in the extended depletion region. This strong electric field causes an avalanche multiplication in the depletion layer region extending to the portion of the first semiconductor region 311, and a current based on the amplified charge is output as a signal charge. When light incident on the photoelectric conversion element 102 is photoelectrically converted and an avalanche multiplication occurs in this depletion layer region (an avalanche multiplication region), the generated charge of the first conductivity type is collected into the first semiconductor region 311.

Note that, in FIGS. 7A and 7B, the sixth semiconductor region 316 and the seventh semiconductor region 317 are formed of substantially the same size; however, the size of each semiconductor region is not limited to this. For example, the sixth semiconductor region 316 may be formed larger than the seventh semiconductor region 317, and charge may be collected into the first semiconductor region 311 from a wider range.

The seventh semiconductor region 317 may be of P-type instead of N-type. In this case, the P-type impurity concentration of the seventh semiconductor region 317 is set lower than the P-type impurity concentration of the second semiconductor region 312. This is because when the impurity concentration of the seventh semiconductor region 317 is too high, an avalanche multiplication region is formed between the seventh semiconductor region 317 and the first semiconductor region 311, and the dark count rate (DCR) increases.

Pixels are separated from each other by a pixel isolation portion 324 having a trench structure, and the P-type third semiconductor region 313 formed in the vicinity of the pixel isolation portion 324 separates adjacent photoelectric conversion elements from each other by means of a potential barrier. Since the photoelectric conversion elements are also separated from each other by the potential of the third semiconductor region 313, a trench structure such as the pixel isolation portion 324 is not essential as a pixel isolation portion. Even when the pixel isolation portion 324 having a trench structure is provided, its depth and position are not limited to the configuration illustrated in FIGS. 7A and 7B. The pixel isolation portion 324 may have a structure that penetrates through the first semiconductor layer 300 (deep trench isolation) or may have a structure that does not penetrate through the first semiconductor layer 300. Metal may be embedded within the pixel isolation portion 324 to improve light shielding performance. The pixel isolation portion 324 may be composed of SiO, a fixed charge film, a metal member, Poly-Si, or a combination of several of them. The pixel isolation portion 324 may be configured to surround the entire circumference of the photoelectric conversion element in a plan view or may be configured so as to correspond to only two or more of four sides excluding the corners of the photoelectric conversion element, for example. A voltage may be applied to the embedded member to induce charge at the trench interface to suppress DCR.

A pinning film, a planarization film, and a microlens, which are not illustrated, may further be formed on the light-incident side. A filter layer or the like, which is not illustrated, may further be arranged on the light-incident side. In the filter layer, various optical filters may be used. Examples of the various optical filters include a color filter, an infrared light cut filter, and a monochrome filter. As the color filter, an RGB color filter, an RGBW color filter, or the like can be used.

The first wiring layer 301 includes wiring lines and an insulating film. An interlayer film, which is an insulating film, is provided between the wiring lines and the semiconductor layer and between the wiring lines. The eighth semiconductor region 318 of the first semiconductor layer 300 is connected to an anode electrode 331 and is connected to a wiring line provided in the first wiring layer 301.

Moreover, the first semiconductor region 311 is connected to a cathode electrode 332 and is connected to a wiring line provided in the first wiring layer 301.

The second semiconductor layer 400 includes an insulation isolation region 422 and a transistor that is included in the signal processing unit 103 illustrated in FIG. 4. For example, the transistor is the quenching device 202. At least part of the insulation separation region 422 has a through-region that penetrates through the second semiconductor layer 400, and a through-via 421 is arranged in the through-region.

The second wiring layer 401 includes wiring lines and an insulating film. An interlayer film, which is an insulating film, is provided between the wiring lines and the semiconductor layer and between the wiring lines. The wiring lines included in the second wiring layer 401 are included in the signal processing unit 103.

The second-substrate rear-surface interlayer film layer 402 includes a bonding portion 333 on the surface on the opposite side from the second semiconductor layer 400. The bonding portion 333 of the second-substrate rear-surface interlayer film layer 402 is in contact with a bonding portion 333 of the first wiring layer 301, and the semiconductor devices of the first substrate 11 and second substrate 21 are electrically connected to each other.

Note that it is also possible to use a configuration in which there is not a bonding portion 333 between the first substrate 11 and the second substrate 21, and a through-via extends from the second wiring layer 401 to the first wiring layer 301 or the first semiconductor layer 300, thereby electrically connecting the semiconductor devices of the first substrate 11 and the second substrate 21.

In the present embodiment, the cathode terminal of the APD of the first semiconductor layer 300 is connected to the second wiring layer 401 of the second substrate 21 with one or more of the wiring lines of the first wiring layer 301, the bonding portion 333, and the through-via 421.

Next, FIGS. 6B, 8, 9A, and 9B are used to describe the planar arrangement of elements disposed in or on the second substrate 21 and the planar and cross-sectional structures of a quench device section disposed on the second substrate 21. FIG. 6B illustrates a quenching device section 411, a first circuit section 412, and a second circuit section 413 disposed on the second substrate 21. Furthermore, FIG. 6B illustrates the through-via 421 and the insulation isolation region 422. The quenching device section 411 includes the quenching device 202 illustrated in FIG. 4, the first circuit section 412 includes the waveform shaping unit 210 illustrated in FIG. 4, and the second circuit section 413 includes the counter circuit 211 and the selection circuit 212 illustrated in FIG. 4.

In FIG. 6B, the quenching device section 411, the first circuit section 412, and the second circuit section 413 are each a circuit block and are separated from each other by the insulation isolation region 422; however, the quenching device section 411, the first circuit section 412, and the second circuit section 413 are not necessarily separated from each other. The insulation isolation region 422 may also be disposed within each block as an element isolation region.

Moreover, the entire insulation isolation region 422 does not necessarily penetrate through the second semiconductor layer 400, and it is also possible to use a configuration in which only part of the insulation isolation region 422 where the through-via 421 is present penetrates through the second semiconductor layer 400.

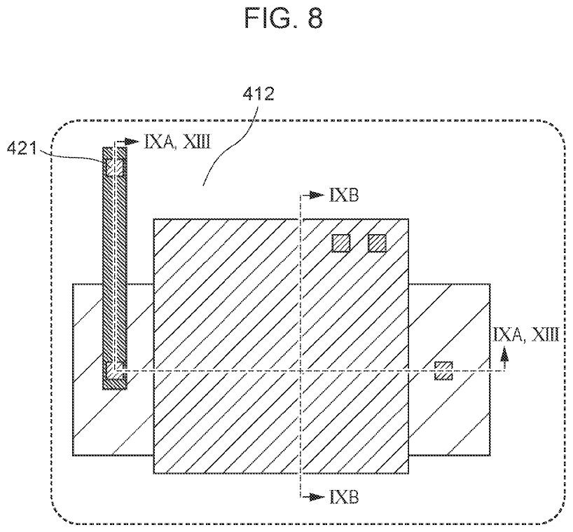

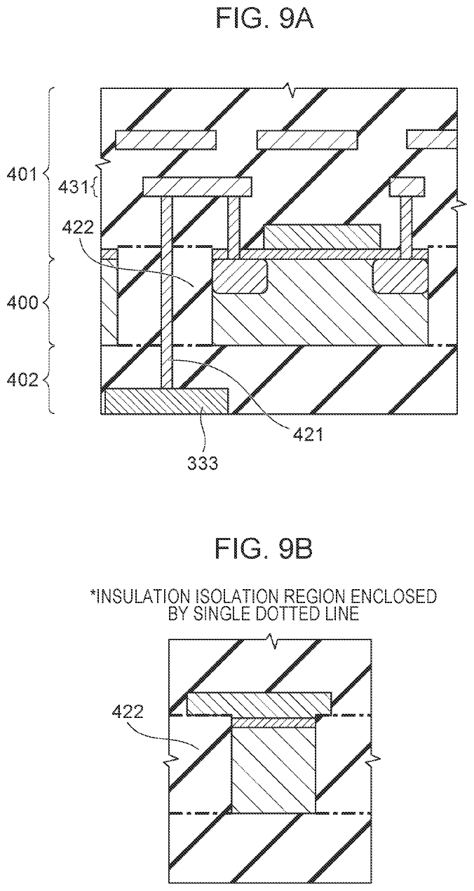

FIG. 8 illustrates an enlarged plan view of the quenching device section. FIG. 9A illustrates a cross-sectional view of a section taken along IXA-IXA of FIG. 8, and FIG. 9B illustrates a cross-sectional view of a section taken along IXB-IXB in FIG. 8.

The quenching device 202 has a MOS transistor structure. One end of the source and drain of the MOS transistor included in the quenching device 202 is electrically connected to the cathode potential of the APD 201, and the other end is connected to the voltage VH. In the present embodiment, the quenching device 202 and the cathode potential of the APD 201 are connected to each other with the through-via 421 and a first wiring section 431 of the second wiring layer 401 interposed therebetween. In this case, the first wiring section 431 refers to the wiring section closest to the front surface of the second semiconductor layer 400 in the second wiring layer 401. The wiring sections above the first wiring section 431 are expressed as a second wiring section and a third wiring section, sequentially from the front surface side of the second semiconductor layer 400. As illustrated in FIG. 9B, the gate width of the MOS transistor included in the quenching device 202 is defined by the insulation isolation region 422.

Effects of the present embodiment will be described below.

In a photoelectric conversion device using APDs, an increase in the area where the signal processing units 103 can be arranged contributes to improved imaging performance. Thus, the area of the signal processing units 103 can be maximized by assigning the photoelectric conversion elements 102 and the signal processing units 103 to the respective substrates and creating a multilayer structure. In addition, variations in the characteristics of the quenching devices 202, such as threshold variations, cause degradation of image quality characteristics. It is thus important for photoelectric conversion apparatuses that use APDs to suppress variations in the characteristics of the quenching devices 202.

Based on these considerations, in the present embodiment, the photoelectric conversion element 102 and the signal processing unit 103 are electrically connected within each pixel region by the through-via 421, which is for electrical connection between the substrates as described above, and an increase in the area where the signal processing units 103 are arranged is achieved. In addition, the insulation isolation region 422 for arranging the through-via 421 also serves to isolate the quenching device 202 and defines the gate width, thereby improving the characteristic variation tolerance of the quenching devices 202 without sacrificing the area where elements are arranged.

In the present embodiment, the through-via 421 leading to the cathode terminal of the APD and the quenching device section 411 are arranged next to each other. This arrangement allows the wiring length to be shortened and the cathode capacitance to be reduced. The smaller the cathode capacitance, the more time and power required for recharging can be reduced. The through-via 421 and the quenching device 202 are connected to each other with only the first wiring section 431 interposed therebetween. This arrangement allows the wiring length to be shortened and the cathode capacitance to be reduced.

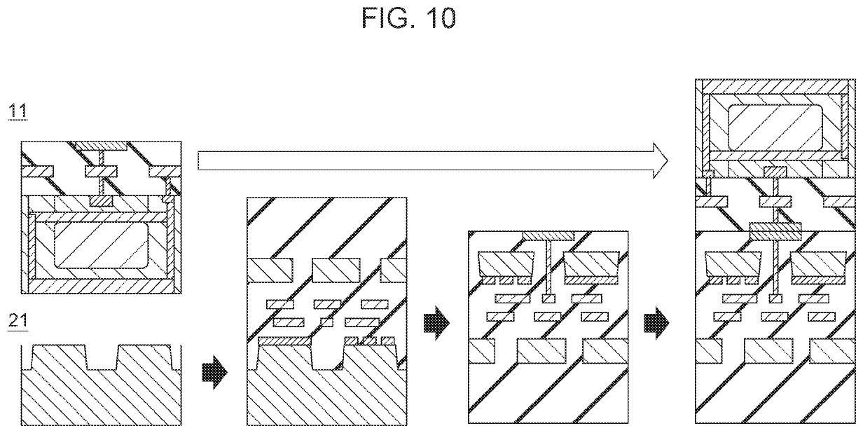

FIG. 10 is a flow diagram illustrating a manufacturing method of the photoelectric conversion apparatus according to the present embodiment.

The photoelectric conversion element 102, the first wiring layer 301, and the bonding portion 333 are formed in the first substrate 11.

The insulation isolation region 422 is formed, and thereafter the semiconductor devices included in the signal processing unit 103 and the second wiring layer 401 are formed in the second substrate 21. The second semiconductor layer 400 is then thinned from the rear surface side to expose at least part of the insulation isolation region 422. This exposed region is called a through-region. Thereafter, an interlayer film is formed on the rear surface side, the through-via 421 is formed in the through-region in the insulation separation region, and the bonding portion 333 is formed. Lastly, the bonding portion 333 of the first substrate 11 and the bonding portion 333 of the second substrate 21 are electrically connected to each other by joining them together.

In the present embodiment, the insulation separation region 422 has a tapered shape with a larger opening diameter on the front surface side than on the rear surface side. This arrangement allows uniform formation of the insulating film that constitutes the insulation separation region 422.

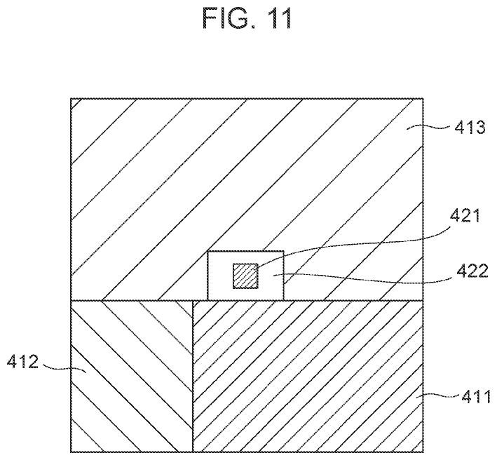

FIG. 11 illustrates a modification example of the plan schematic diagram of the second substrate corresponding to FIG. 6B. In FIG. 6B, the circuit blocks (the quenching device section 411, the first circuit section 412, the second circuit section 413) are separated from each other by the insulation isolation region 422; however, in FIG. 11, part of the quenching device section 411 is in contact with the insulation separation region 422. Even with this configuration, the effects of the present embodiment can be obtained.

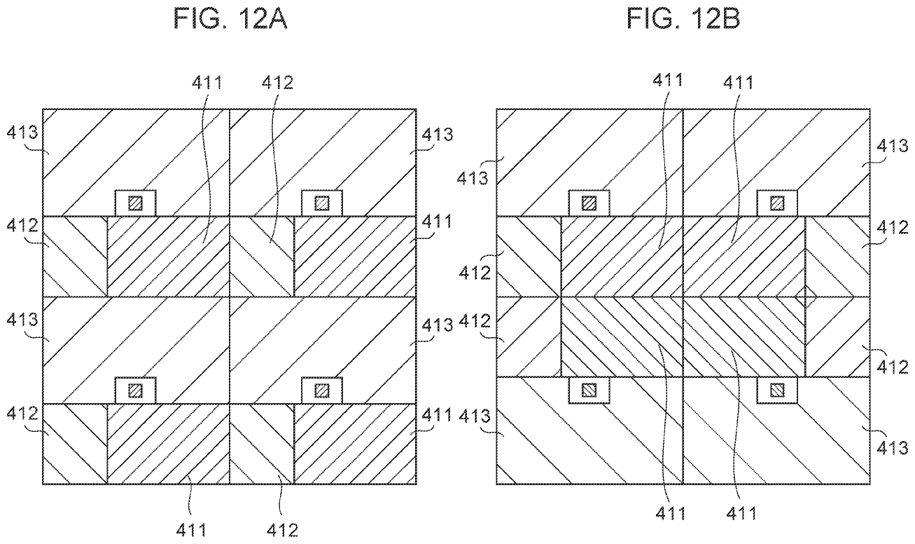

FIGS. 12A and 12B illustrate plan schematic diagrams in which the pixel illustrated in FIG. 11 is arranged in a 2×2 pixel configuration. FIG. 12A illustrates an example in which the pixels exhibit translational symmetry in their arrangement, and FIG. 12B illustrates an example in which the pixels exhibit mirror symmetry in their arrangement.

An advantage of the arrangement in FIG. 12A is its high tolerance to manufacturing variation. This is because the effect of alignment variation (misalignment) during element formation and impurity implantation occurs to the same degree in all pixel circuits.

In contrast, an advantage of the arrangement in FIG. 12B is that the same circuit blocks of the pixel circuits, such as the quenching device sections 411, are adjacent to each other, so that elements can be more efficiently arranged. When there are a plurality of types of elements, for example, high-voltage elements and low-voltage elements, it is usually necessary to provide more space between elements of different types next to each other than between elements of the same type next to each other. Thus, elements can be arranged more efficiently in a case where the same circuit blocks of the pixel circuits are configured to be next to each other.

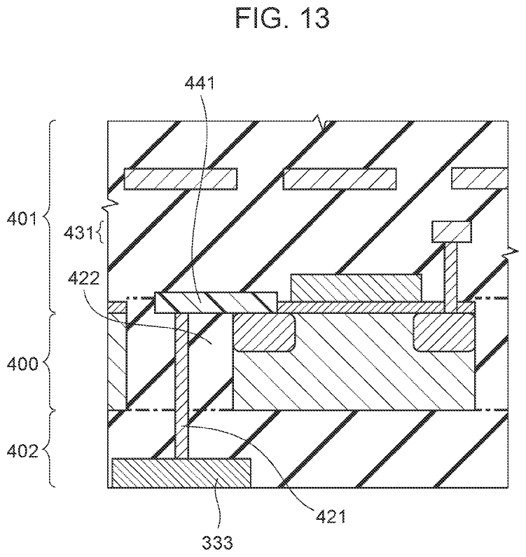

FIG. 13 is a modification example of an enlarged cross-sectional view of the quenching device section illustrated in FIG. 9A. FIG. 13 illustrates a cross-sectional view taken along XIII-XIII of FIG. 8. FIG. 13 differs from FIG. 9A in that the through-via 421 is connected to one end of the MOS transistor, which is the quenching device, with a polysilicon wiring line 441, which is included in the second substrate 21, interposed therebetween. This arrangement can further shorten the wiring length and reduce the cathode capacitance to a greater extent compared to the connection established through the wiring layer 401.

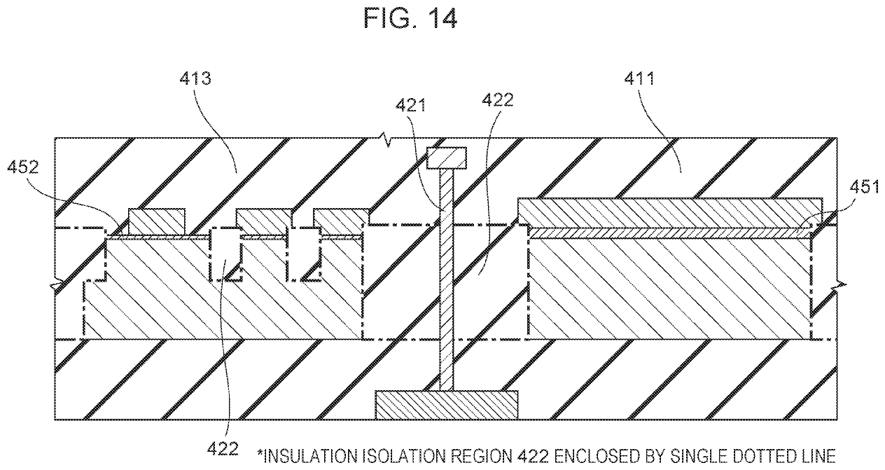

FIG. 14 is an example of an enlarged cross-sectional view of the second substrate taken along XIV-XIV illustrated in FIGS. 6A and 6B. FIG. 14 illustrates a cross-section of the MOS transistor (a first element) of the quenching device section 411, a MOS transistor (a second element) of the second circuit section 413, the insulation isolation region 422, and the through-via 421.

A first gate oxide film 451 having a first thickness is arranged as the gate oxide film in the MOS transistor of the quenching device section 411, and a second gate oxide film 452 having a second thickness is arranged as the gate oxide film in the MOS transistor of the second circuit section 413. In general, the thicker the gate oxide film, the higher the breakdown voltage of the transistor. Thus, transistors with different breakdown voltages may be arranged in the second substrate 21.

For the quenching device 411 to which the cathode potential node of the APD is connected, a high-voltage transistor having a thicker gate oxide film can be used to stabilize the characteristics. For the transistor of a circuit included in the second circuit section 413, a thinner gate oxide film can be used to achieve miniaturization and higher speed.

In a case where elements with different breakdown voltages are in or on the same substrate, the space between elements with different breakdown voltages can be wider than the space between elements with the same breakdown voltage for manufacturing purposes. The space between the through-via 421 and each element can be also wider than the space between elements with the same breakdown voltage. From this perspective, the through-via 421 can be provided between a circuit block having a first oxide film (in this case, the quenching device section 411) and a circuit block having a second oxide film (in this case, the second circuit section 413).

As illustrated in FIG. 14, the insulation isolation region 422 may have different depths depending on its location, or the insulation isolation region 422 may have a stepped shape. The insulation isolation region 422 may also have a region that does not penetrate through the second semiconductor layer 400. Shallow insulation isolation regions are formed in the second circuit section 413 and so forth where miniaturization and higher speed are required, and a deep insulation isolation region is used in the region for arranging the through-via 421, thereby improving the efficiency of element arrangement.

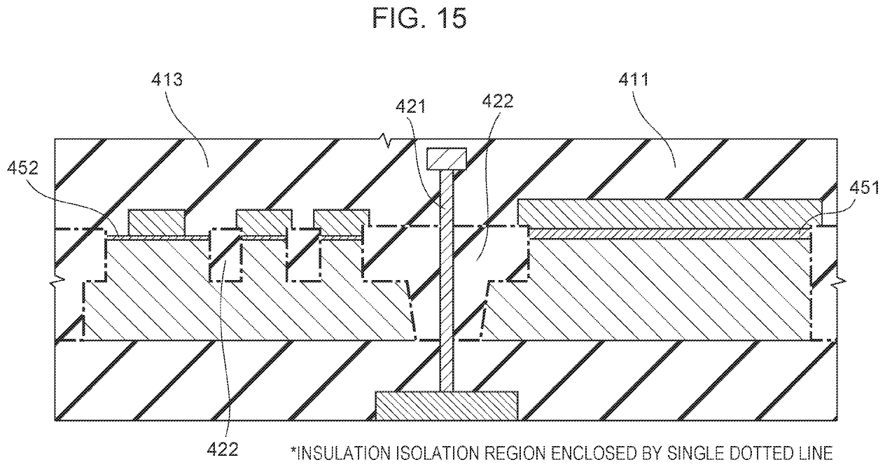

FIG. 15 is a modification example of an enlarged cross-sectional view of the second substrate taken along XV-XV illustrated in FIGS. 6A and 6B. FIG. 15 differs from FIG. 14 in that the insulation isolation region 422 for arranging the through-via 421 has a stepped shape. It is sufficient that the through-region where the insulation isolation region 422 penetrates through the second semiconductor layer 400 be formed at least at the portion where the through-via 421 is arranged. By combining the through-region with shallow insulation isolation regions for finer fabrication, the efficiency of element arrangement can be improved.

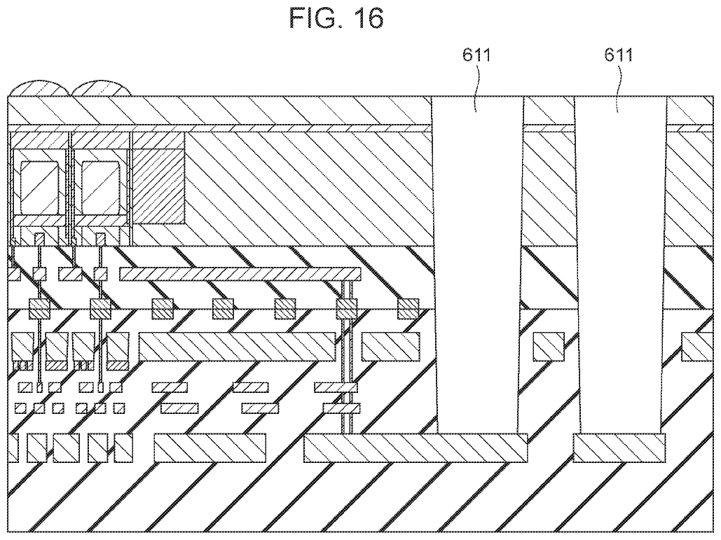

FIG. 16 is a cross-section schematic diagram of the photoelectric conversion apparatus, the cross-section schematic diagram illustrating from an end of the pixel region to an end of the sensor substrate. An end portion of the photoelectric conversion apparatus has a pad portion 611 for supplying voltage from outside. FIG. 16 illustrates a configuration in which all pads of the pad portion 611 are connected to the wiring layer on the second substrate side. The pads are connected to the first substrate with the above-described through-vias interposed therebetween. With this configuration, the pads can be formed in a single process, thereby simplifying manufacturing. In this case, a power supply connected to the first substrate is, for example, an anode voltage.

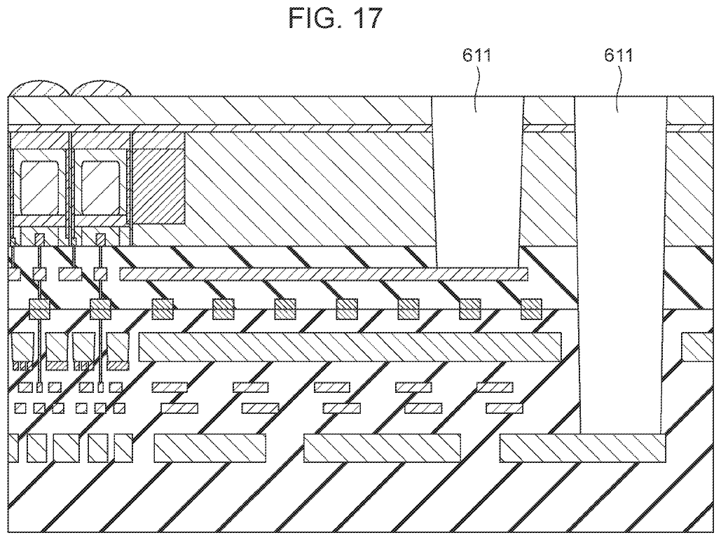

FIG. 17 is a modification example of the pad portion 611. FIG. 17 illustrates a configuration that includes a pad connected to the wiring layer on the first substrate side and a pad connected to the wiring layer on the second substrate side. Although formation of the pads requires a plurality of processes, the voltage to be supplied to the second substrate can be supplied with lower resistance than in the configuration illustrated in FIG. 16. In addition, the voltage VL applied to the APD of the first substrate is a significantly high voltage in absolute terms (for example, −30 V), and it is desirable that the pad for the APD be arranged only in the first substrate. In the form illustrated in FIG. 17, the voltage VL can be assigned to the pad connected to the first substrate.

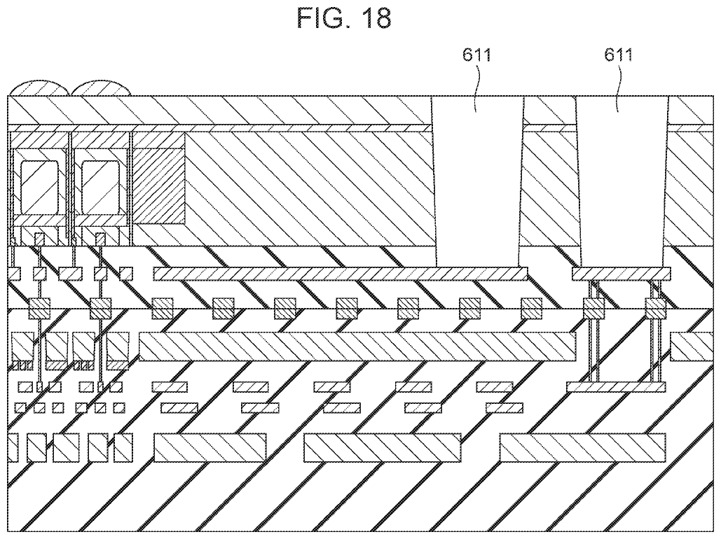

FIG. 18 illustrates a configuration in which all the pads are connected to the wiring layer on the first substrate side. Electrical connection to the second substrate is established through the through-vias described above. With this configuration, the pads can be formed in a single process, thereby simplifying manufacturing.

### Second Embodiment

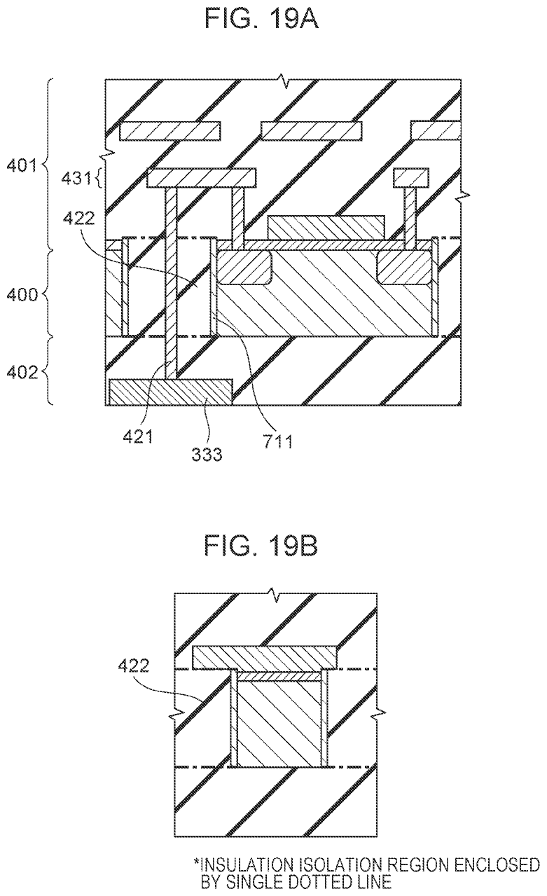

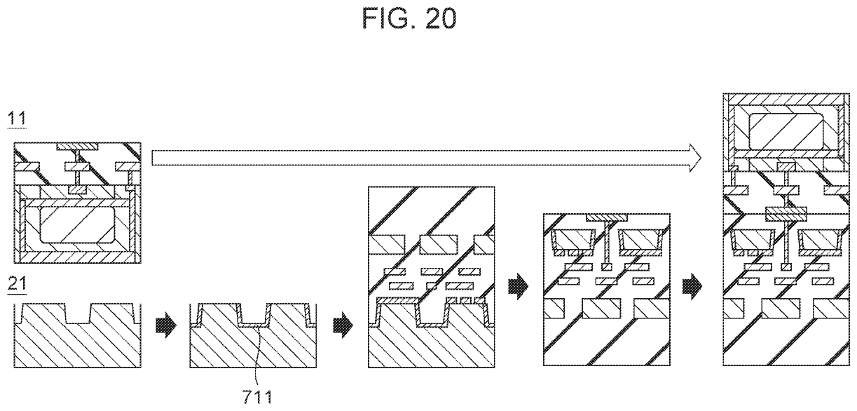

A photoelectric conversion apparatus according to a second embodiment will be described using FIGS. 19A to 20. In the following, points that differ from the first embodiment are mainly described, and common description will be omitted.

FIGS. 19A and 19B illustrate enlarged cross-sectional views of the quenching device section. FIGS. 19A and 19B are diagrams corresponding to FIGS. 9A and 9B of the first embodiment. The second embodiment differs from the first embodiment in that an inner wall oxide film 711 is arranged on the side walls of the insulation isolation region 422. Inner wall oxide films formed at the Si interface by thermal oxidation treatment performed at high temperatures (800 to 1100° C.) are known to be dense and extremely stable and have excellent electrical, mechanical, thermal, and chemical characteristics. Thus, the transistor characteristics can be improved by arranging the inner wall oxide films on the side walls of the element isolation portion.

FIG. 20 is a flow diagram illustrating a manufacturing method. FIG. 20 corresponds to FIG. 10 of the first embodiment. FIG. 20 differs from FIG. 10 in that the inner wall oxide film 711 is formed in a process between the formation process of the insulation isolation region 422 and the semiconductor device formation process. As mentioned above, thermal oxidation treatment is performed at temperatures of 800 to 1100° C. This temperature range generally belongs to the highest temperature range of other heat treatment temperatures in the wafer fabrication process.

Thus, in one embodiment, thermal oxidation is not performed after the process that is performed at a lower temperature and can be performed early in the wafer process before transistor formation. For example, the melting point of Al used in metal wiring is 660° C., and thermal oxidation cannot be performed after wiring processing. Note that this insulation isolation region 422 and the inner wall oxide film 711 may be formed by the shallow trench isolation (STI) method, which is a common process in the wafer fabrication process.

### Third Embodiment

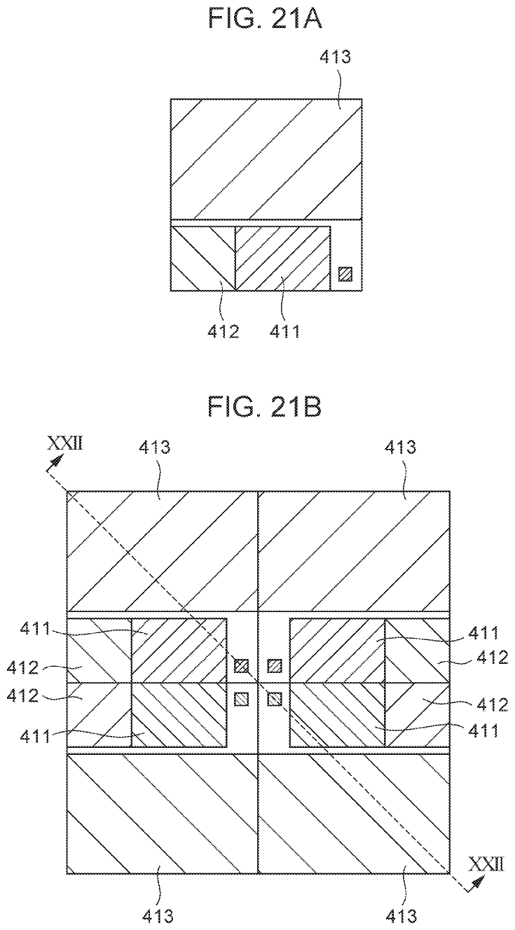

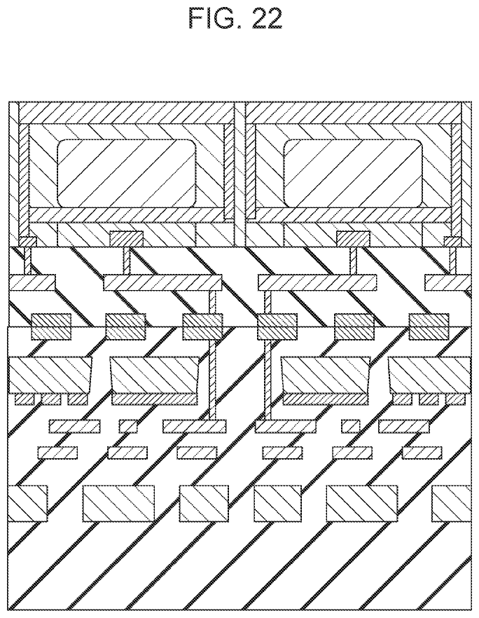

A photoelectric conversion apparatus according to a third embodiment will be described using FIGS. 21A to 22. In the following, points that differ from the first embodiment are mainly described, and common description will be omitted.

FIGS. 21A and 21B illustrates a plan schematic diagram of the second substrate and a plan schematic diagram in which the pixel is arranged in a 2×2 pixel configuration. FIG. 21A and FIG. 21B correspond to FIG. 6B and FIGS. 12A and 12B of the first embodiment. FIG. 22 is a cross-section schematic diagram taken along XXII-XXII of FIG. 21. The third embodiment differs from the first embodiment in that the through-vias are not arranged at an equal pitch and a plurality of through-vias are concentrated in one location. This configuration makes it possible to reduce the size of the through-region for arranging through-vias in the insulation isolation region, thereby improving the layout efficiency of the second substrate.

### Fourth Embodiment

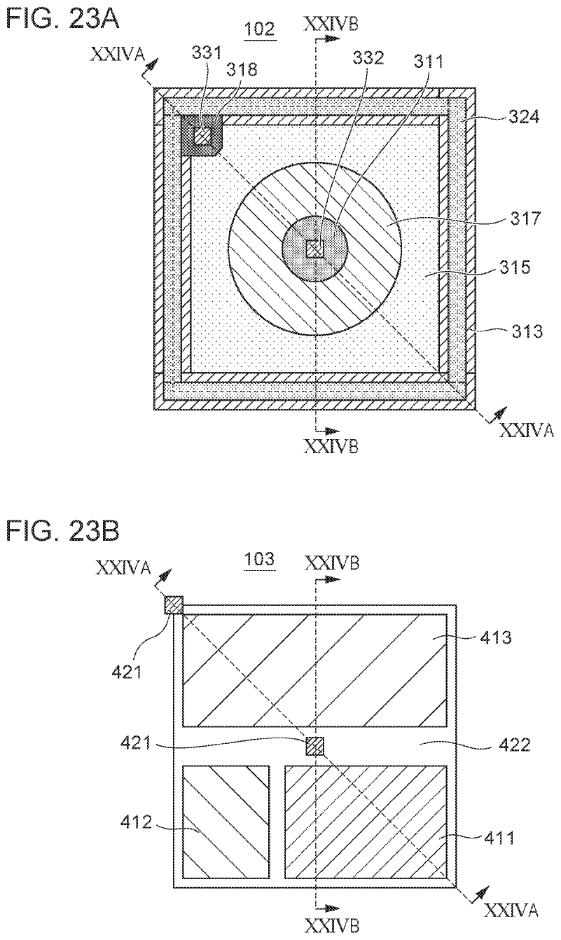

A photoelectric conversion apparatus according to a fourth embodiment will be described using FIGS. 23A to 25B.

In the following, points that differ from the first embodiment are mainly described, and common description will be omitted.

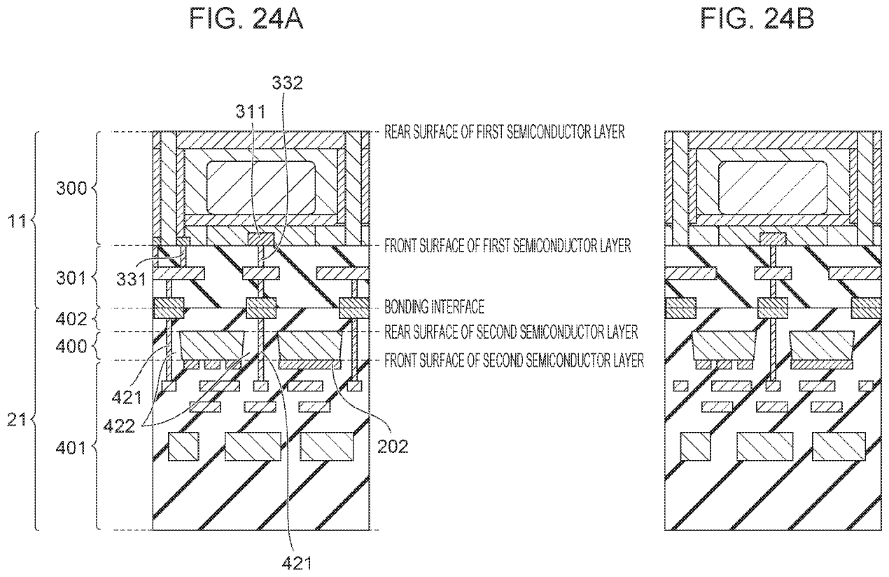

FIGS. 23A and 23B correspond to FIGS. 6A and 6B of the first embodiment and illustrate plan schematic diagrams. FIGS. 24A and 24B correspond to FIGS. 7A and 7B of the first embodiment. FIG. 24A illustrates a cross-section schematic diagram taken along XXIVA-XXIVA of FIGS. 23A and 23B, and FIG. 24B illustrates a cross-section schematic diagram taken along XXIVB-XXIVB of FIGS. 23A and 23B. The present embodiment differs from the first embodiment in that one pixel region includes a plurality of through-vias 421.

Each APD of the first substrate needs at least the cathode electrode and anode electrode as described above. Examples in which only the output of the cathode electrode is electrically connected to the second substrate by the through-via have been described so far; however, in the present embodiment, the anode electrode is also electrically connected to the second electrode by a through-via. In a case where a configuration is used in which the anode voltage is supplied from the portion surrounding the pixels as in the first embodiment, a voltage drop or the like may occur in the center of the pixels. In contrast, with the configuration described in the present embodiment, the anode voltage can be supplied to each pixel, so that the voltage can be supplied to the APD in a more stable manner.

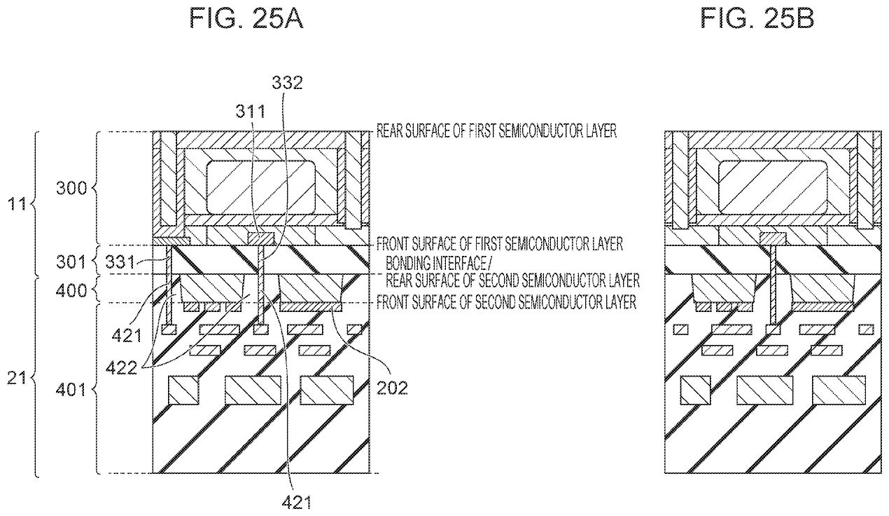

FIGS. 25A and 25B are modification examples of the cross-section schematic diagrams. FIG. 25A illustrates a cross-section schematic diagram taken along XXVA-XXVA of FIGS. 23A and 23B, and FIG. 25B illustrates a cross-section schematic diagram taken along XXVB-XXVB of FIGS. 23A and 23B. As described in the first embodiment, it is also possible to use a configuration in which there is not a bonding portion 333, the through-vias 421 extend from the second wiring layer 401 to the first wiring layer 301 or the first semiconductor layer 300, and the elements of the first substrate 11 are electrically connected to the elements of the second substrate 21. FIGS. 25A and 25B illustrate cross-section schematic diagrams of the configuration. As described above, each APD needs at least the cathode electrode and the anode electrode. As long as a configuration is used in which connection to both electrodes are established by the through-vias 421 from the second substrate 21, only the through-vias 421 are required in the first wiring layer 301. This configuration can simplify the manufacturing process of the first substrate 11. In addition, the cathode capacitance can be further reduced.

### Fifth Embodiment

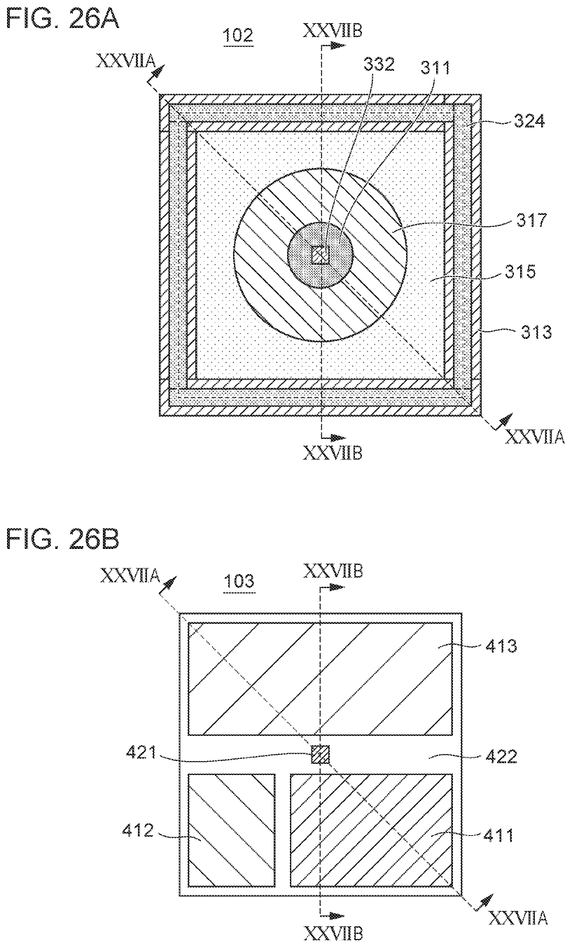

A photoelectric conversion apparatus according to a fifth embodiment will be described using FIGS. 26A to 28B.

In the following, points that differ from the first embodiment are mainly described, and common description will be omitted.

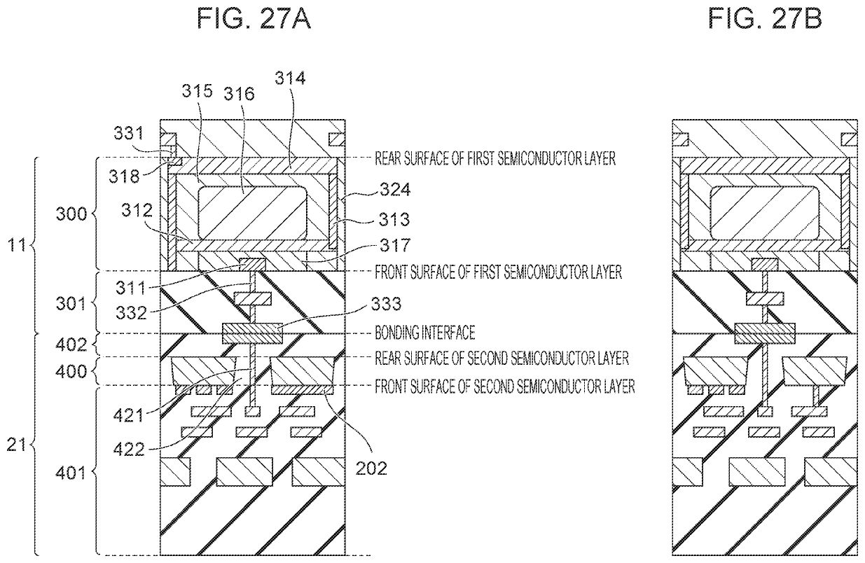

FIGS. 26A and 26B correspond to FIGS. 6A and 6B of the first embodiment and illustrate plan schematic diagrams. FIGS. 27A and 27B correspond to FIGS. 7A and 7B of the first embodiment. FIG. 27A illustrates a cross-section schematic diagram taken along XXVIIA-XXVIIA of FIGS. 26A and 26B, and FIG. 27B illustrates a cross-section schematic diagram taken along XXVIIB-XXVIIB of FIGS. 26A and 26B. The present embodiment differs from the first embodiment in that the anode electrode 331 and the eighth semiconductor region 318 connected to the anode electrode 331 are on the front surface side of the first semiconductor layer. Pixels using APDs are difficult to miniaturize in order to maintain the breakdown voltage between the anode and cathode; however, this configuration allows the anode and cathode to be separated in a planar manner, and this is advantageous for pixel miniaturization.

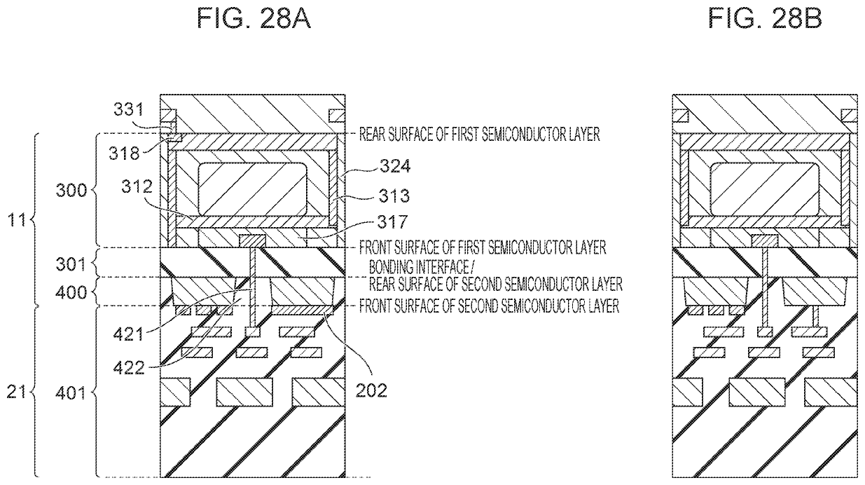

FIGS. 28A and 28B are modification examples of the cross-section schematic diagrams. FIG. 28A illustrates a cross-section schematic diagram taken along XXVIIIA-XXVIIIA of FIGS. 26A and 26B, and FIG. 28B illustrates a cross-section schematic diagram taken along XXVIIIB-XXVIIIB of FIGS. 26A and 26B. Similar to the configuration illustrated in FIGS. 25A and 25B of the fourth embodiment, the through-via 421 is directly bonded from the second wiring layer 401 to the first semiconductor layer 300 without using the bonding portion 333. When this configuration is used, only one through-via is needed for each pixel in the present embodiment, in which the anode voltage is supplied from the rear surface of the first semiconductor layer, and a broader area of the second substrate on which the elements can be arranged can be ensured than in the configuration illustrated in the fourth embodiment.

### Sixth Embodiment

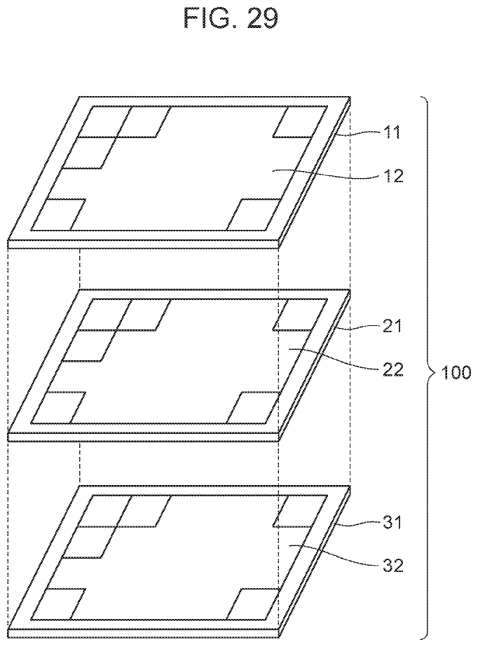

A photoelectric conversion apparatus according to a sixth embodiment will be described using FIGS. 29 to 36.

In the following, points that differ from the first embodiment are mainly described, and common description will be omitted.

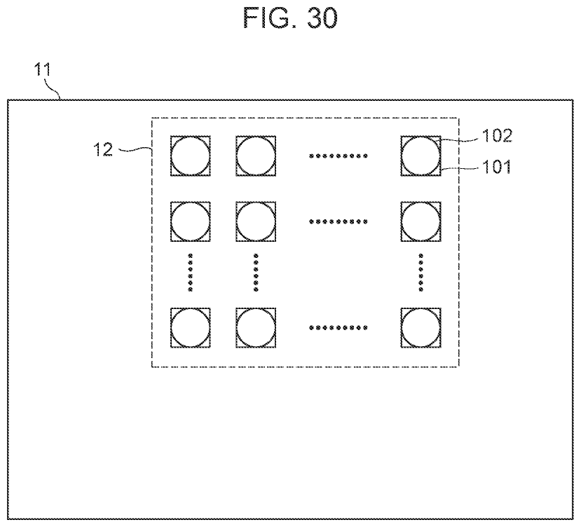

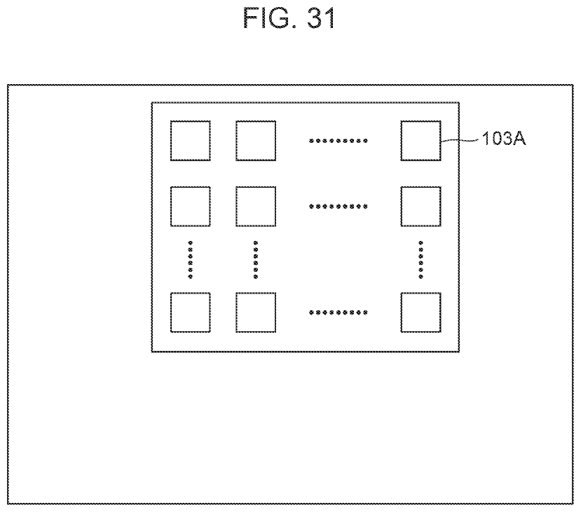

FIG. 29 is a diagram illustrating the configuration of a photoelectric conversion apparatus 100 of a multilayer type according to the sixth embodiment of the present disclosure. FIG. 30 is a diagram of the configuration of the sensor substrate 11. FIG. 31 is a diagram of the configuration of the circuit substrate 21.

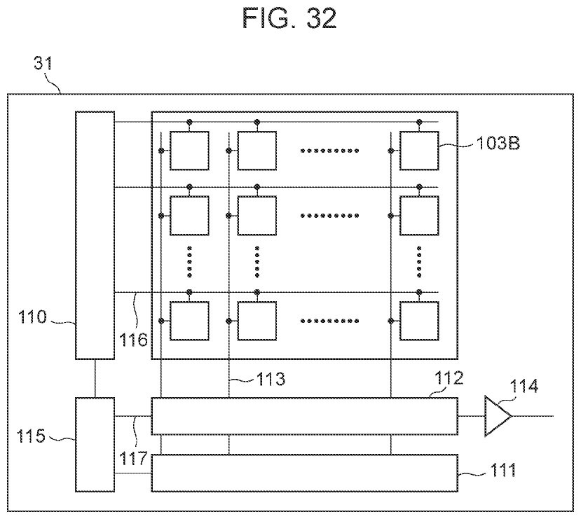

FIG. 32 is a diagram of the configuration of a second circuit substrate 31. The photoelectric conversion apparatus 100 is constituted by stacking and electrically connecting three substrates, which are the sensor substrate 11, the circuit substrate 21, and the second circuit substrate 31. In the following, the sensor substrate 11, the circuit substrate 21, and the second circuit substrate 31 will be described as chips obtained by dicing; however, the sensor substrate 11, the circuit substrate 21, and the second circuit substrate 31 are not limited to such chips. For example, each substrate may be a wafer. The individual substrates may be stacked one on top of the other in a wafer state and then be subjected to dicing. Alternatively, the individual substrates may also be divided into chips, and chips may be staked one on top of the other and joined to each other. The sensor substrate 11 may also be called a first substrate 11, the circuit substrate 21 may also be called a second substrate 21, and the second circuit substrate 31 may also be called a third substrate 31.

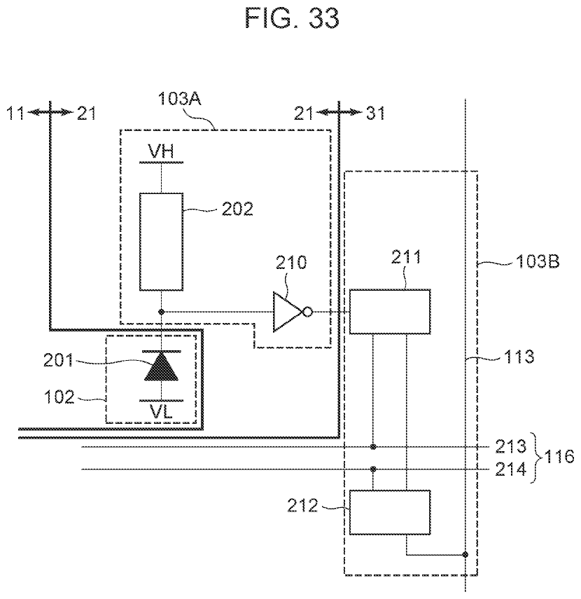

The sixth embodiment differs from the first embodiment in that the second circuit substrate 31 and a second circuit region 32 are added. The signal processing sections 103 are arranged across two substrates, which are the circuit substrate 21 and the second circuit substrate 31. The signal processing units arranged in or on the circuit substrate 21 are treated as signal processing units 103A, and the signal processing units arranged in or on the second circuit substrate 31 are treated as signal processing units 103B. FIG. 33 is an example of a block diagram including equivalent circuits of FIGS. 30, 31, and 32. The signal processing unit 103A includes the quenching device 202 and the waveform shaping unit 210, and the signal processing unit 103B includes the counter circuit 211, the selection circuit 212, the signal line 113, and the drive lines 213 and 214.

The photoelectric conversion elements 102 illustrated in FIG. 30 are electrically connected to the signal processing units 103A illustrated in FIG. 31 through connection wiring lines provided for the respective pixels. Furthermore, in the present embodiment, the signal processing units 103A illustrated in FIG. 31 are electrically connected to the signal processing units 103B illustrated in FIG. 32 through connection wiring lines provided for the respective pixels.

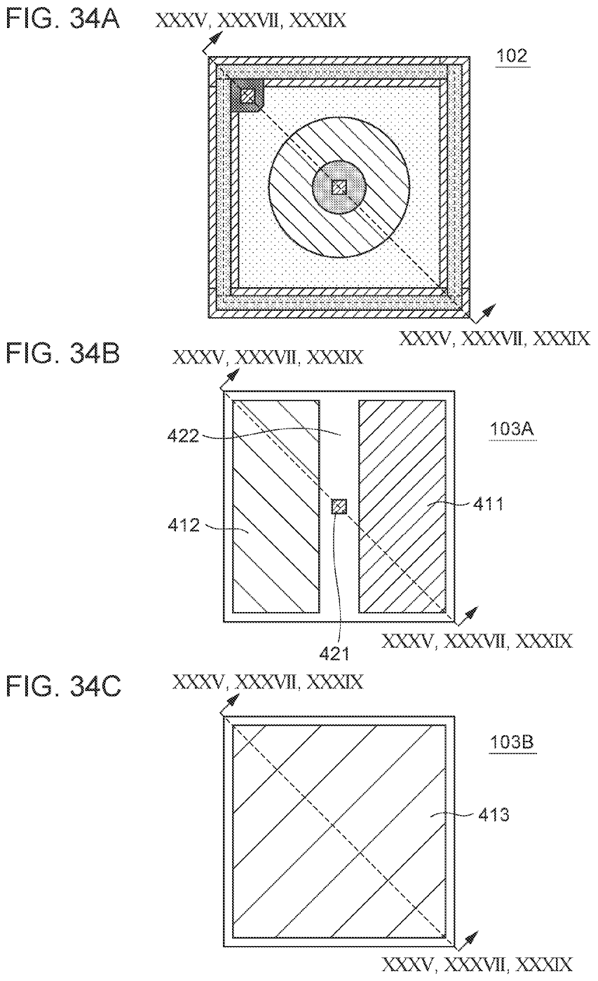

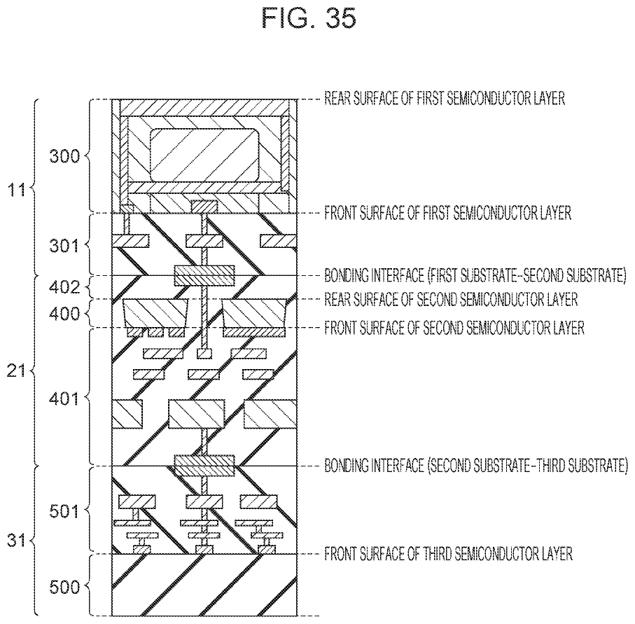

FIGS. 34A, 34B, and 34C are plan schematic diagrams of the first substrate 11, the second substrate 21, and the third substrate 31. FIG. 35 is a cross-section schematic diagram taken along XXXV-XXXV of FIGS. 34A to 34C. The third substrate 31 includes a third semiconductor layer 500 and a third wiring layer 501. The first substrate 11 and the second substrate 21 are connected so that the front surface of the first semiconductor layer 300 and the rear surface of the second semiconductor layer 400 face each other, similarly to as in the first embodiment. The second substrate 21 and the third substrate 31 are connected so that the front surface of the second semiconductor layer 400 and the front surface of the third semiconductor layer 500 face each other. This bonding is performed using a metal bonding (hybrid bonding) technology, for example, using Cu.

Normally, when hybrid bonding is used to bond wiring layers facing each other, it is difficult to electrically connect yet another semiconductor layer on a pixel-by-pixel basis. However, by using the configuration illustrated in the present embodiment, it is possible to achieve three-layer stacking that is obtained by electrically connecting the three layers on a pixel-by-pixel basis. With the structure in which the three semiconductor layers are stacked, the arrangement area for signal processing circuits can be increased, so that higher functionality can be achieved.

Furthermore, separating elements with different breakdown voltages among the different semiconductor layers can further increase space for arranging elements. For example, in the present configuration, the quenching device 202 and the waveform shaping unit 210 can be high-voltage MOS transistors. In contrast, the counter circuit 211 and the selection circuit 212 do not require high withstand voltage performance. In such a case, the quenching device 202 and the waveform shaping unit 210 can be arranged in or on the second substrate 21, and the counter circuit 211 and the selection circuit 212 can be arranged in or on the third substrate 31.

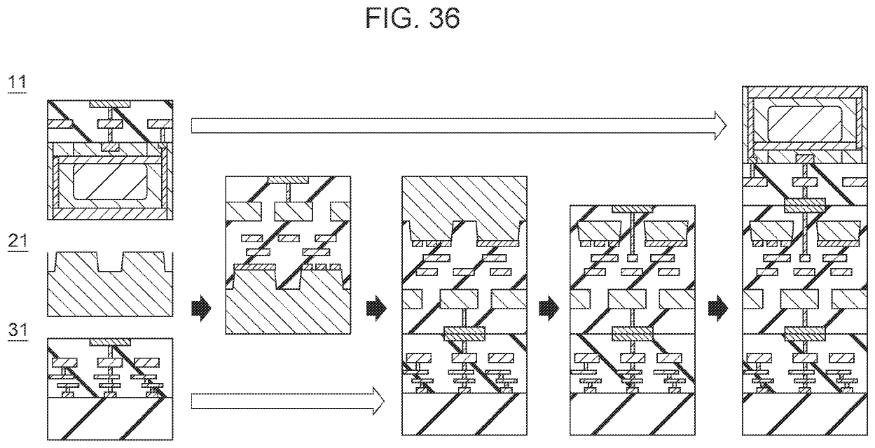

FIG. 36 illustrates a stacking flow diagram of the present embodiment. An APD device, a wiring layer, and a connection portion are formed in the first substrate 11. A semiconductor device, a wiring layer, and a connection portion included in the signal processing unit 103B are formed in the third substrate 31. Regarding the second substrate 21, the insulation isolation region 422 is first formed and thereafter a semiconductor device, a wiring layer, and a bonding portion included in the signal processing unit 103A are formed in the second substrate 21.

Subsequently, the third substrate 31 and the second substrate 21 are joined together and electrically connected to each other. Thereafter, the second semiconductor layer of the second substrate 21 is thinned from the rear surface side to expose at least part of the insulation isolation region 422. This exposed region is called a through-region.

Further thereafter, an interlayer film is formed on the rear surface side of the second semiconductor layer, a through-via is formed in the through-region in the insulation isolation region 422, and a bonding portion is formed in the surface on the opposite side from the third substrate 31.

Lastly, the first substrate 11 and the second substrate 21 are joined together and electrically connected by the bonding portion.

### Seventh Embodiment

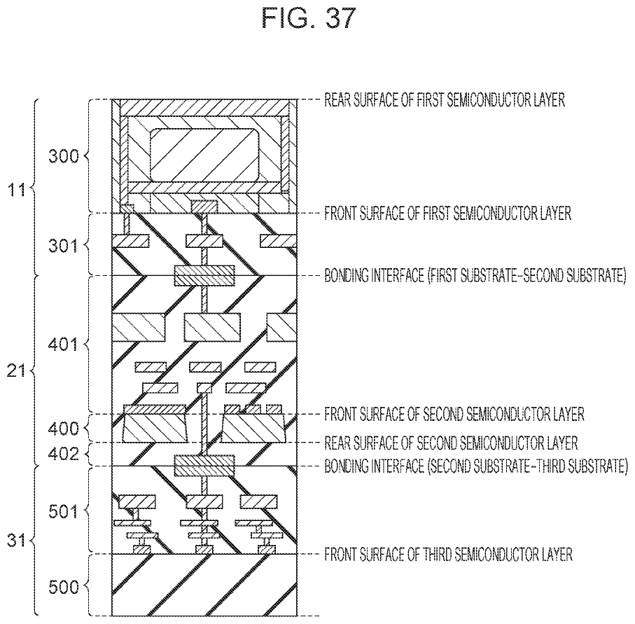

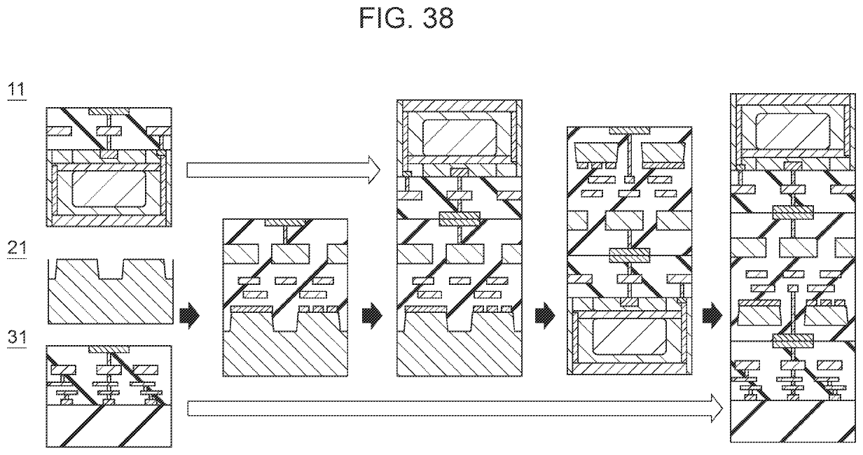

A photoelectric conversion apparatus according to a seventh embodiment will be described using FIGS. 37 and 38. In the following, points that differ from the first embodiment and the sixth embodiment are mainly described, and common description will be omitted.

FIG. 37 is a cross-section schematic diagram taken along XXXVII-XXXVII of FIGS. 34A to 34C described in the sixth embodiment.

The third substrate 31 includes the third semiconductor layer 500 and the third wiring layer 501. Unlike the first embodiment, the first substrate 11 and the second substrate 21 are connected so that the front surface (the first plane) of the first semiconductor layer 300 and the front surface (the third plane) of the second semiconductor layer 400 face each other. The second substrate 21 and the third substrate 31 are connected so that the rear surface (the fourth plane) of the second semiconductor layer 400 and the front surface (a fifth plane) of the third semiconductor layer 500 face each other. The seventh embodiment differs from the sixth embodiment in that the substrate connected to the rear surface side of the second semiconductor layer 400 is the third substrate 31. Even with such a configuration, while realizing three-layer stacking, the effects of the arrangement relationship of the insulation isolation region, through-electrode, and quenching device as described in the first to fifth embodiments can be obtained.

FIG. 38 illustrates a stacking flow diagram of the present embodiment. An APD device, a wiring layer, and a connection portion are formed in the first substrate 11. A semiconductor device, a wiring layer, and a connection portion included in the signal processing unit 103B are formed in the third substrate 31. Regarding the second substrate 21, the insulation isolation region 422 is formed and thereafter a semiconductor device, a wiring layer, and a bonding portion included in the signal processing unit 103A are formed in the second substrate 21.

Subsequently, the first substrate 11 and the second substrate 21 are joined together and electrically connected to each other. Thereafter, the second semiconductor layer of the second substrate 21 is thinned from the rear surface side to expose at least part of the insulation isolation region 422. This exposed region is called a through-region.

Further thereafter, an interlayer film is formed on the rear surface side of the second semiconductor layer, a through-via is formed in the through-region in the insulation isolation region 422, and a bonding portion is formed on the surface on the opposite side from the first substrate 11.

Lastly, the third substrate 31 and the second substrate 21 are joined together and electrically connected by the bonding portion.

### Eighth Embodiment

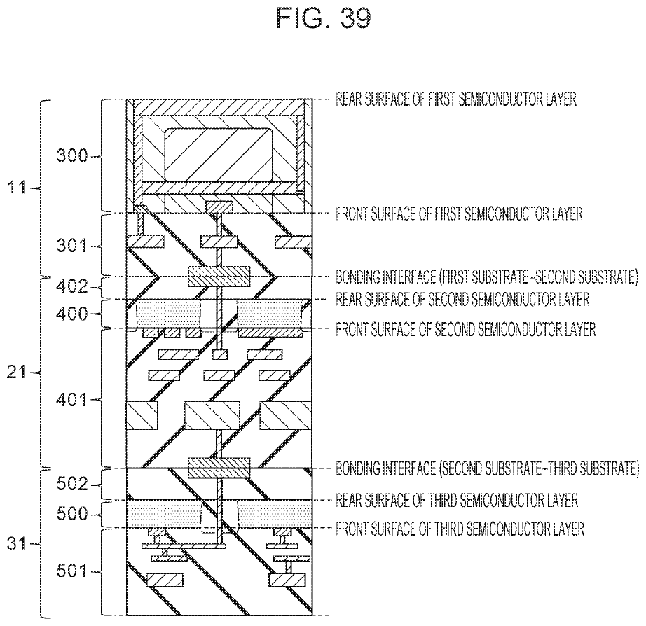

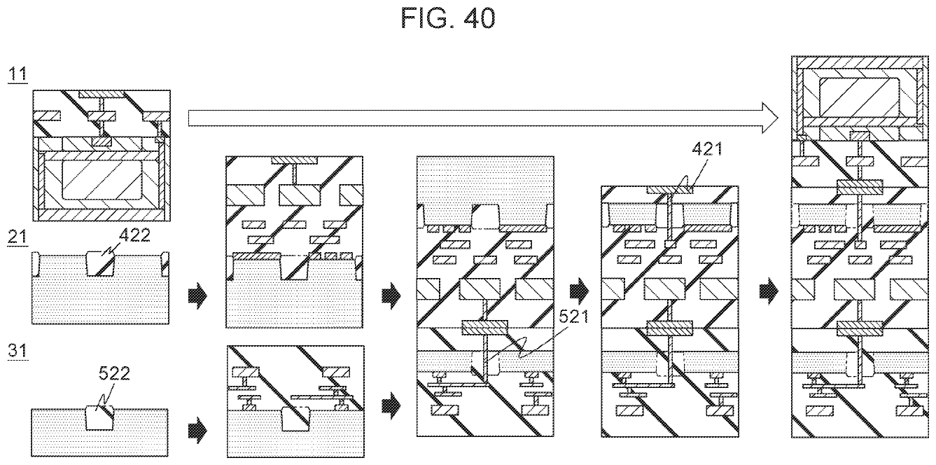

A photoelectric conversion apparatus according to an eighth embodiment will be described using FIGS. 39 and 40. In the following, points that differ from the first embodiment, the sixth embodiment, and the seventh embodiment are mainly described, and common description will be omitted.

FIG. 39 is a cross-section schematic diagram taken along XXXIX-XXXIX of FIGS. 34A to 34C described in the sixth embodiment.

The third substrate 31 includes the third semiconductor layer 500 and the third wiring layer 501. The first substrate 11 and the second substrate 21 are connected so that the front surface of the first semiconductor layer and the rear surface of the second semiconductor layer face each other, similarly to as in the first embodiment. The eighth embodiment differs from the sixth embodiment and the seventh embodiment in that the second substrate 21 and the third substrate 31 are connected so that the front surface (the third plane) of the second semiconductor layer 400 and the rear surface (a sixth plane) of the third semiconductor layer 500 face each other. Even with such a configuration, while realizing three-layer stacking, the effects of the arrangement relationship of the insulation isolation region, through-electrode, and quenching device as described in the first to seventh embodiments can be obtained.

FIG. 40 illustrates a stacking flow diagram of the present embodiment. An APD device, a wiring layer, and a connection portion are formed in the first substrate 11. Regarding the second substrate 21, the insulation isolation region 422 is formed and thereafter a semiconductor device, a wiring layer, and a bonding portion included in the signal processing unit 103A are formed in the second substrate 21.

In contrast, regarding the third substrate 31, the insulation isolation region 522 is formed and thereafter a semiconductor device, a wiring layer, and a bonding portion included in the signal processing unit 103B are formed in the third substrate 31. Further thereafter, an interlayer film is formed on the rear surface side of the third semiconductor layer, a through-via is formed in the through-region in the insulation isolation region 522, and a bonding portion is formed. Subsequently, the first substrate 11 and the second substrate 21 are bonded together and electrically connected to each other. The second semiconductor layer 400 is then thinned from the rear surface side to expose at least part of the insulation isolation region 422. This exposed region is called a through-region. Thereafter, a through-via is formed in the through-region in the insulation separation region to form a bonding portion.

Lastly, the first substrate 11 and the second substrate 21 are joined together and electrically connected by the bonding portion.

### Ninth Embodiment

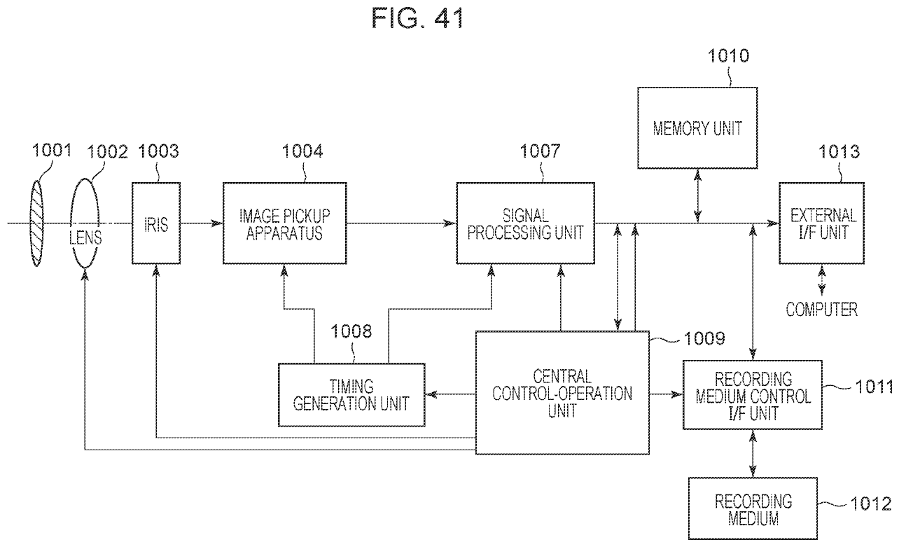

A photoelectric conversion system according to the present embodiment will be described using FIG. 41. FIG. 41 is a block diagram illustrating a schematic configuration of the photoelectric conversion system according to the present embodiment.

The photoelectric conversion apparatuses described in the first to eighth embodiments described above can be applied to various types of photoelectric conversion systems. Examples of the photoelectric conversion systems to which the photoelectric conversion apparatuses described in the first to eighth embodiments described above can be applied include digital still cameras, digital camcorders, surveillance cameras, copiers, fax machines, mobile phones, vehicle-mounted cameras, and observation satellites. The examples of the photoelectric conversion systems also include a camera module having an optical system such as a lens and an image pickup apparatus. FIG. 41 illustrates a block diagram of a digital camera as an example from among these examples.

The photoelectric conversion system illustrated in FIG. 41 includes an image pickup apparatus 1004 as an example of the photoelectric conversion apparatuses and a lens 1002 for causing the image pickup apparatus 1004 to form an optical image of a subject. The photoelectric conversion system further includes an iris 1003 for changing the amount of light passing through the lens 1002 and a barrier 1001 for protecting the lens 1002. The lens 1002 and the iris 1003 are an optical system for concentrating light onto the image pickup apparatus 1004. The image pickup apparatus 1004 is any one of the photoelectric conversion apparatuses according to the embodiments described above and converts the optical image formed by the lens 1002 into an electric signal.

The photoelectric conversion system includes a signal processing unit 1007, which is an image generation unit configured to generate an image by performing processing on an output signal output from the image pickup apparatus 1004. The signal processing unit 1007 performs an operation in which various types of correction or compression are performed as needed to output image data. The signal processing unit 1007 may be formed in or on a semiconductor substrate provided with the image pickup apparatus 1004 or may be formed in or on another semiconductor substrate different from the semiconductor substrate provided with the image pickup apparatus 1004.

The photoelectric conversion system further includes a memory unit 1010 for temporarily storing image data and an external interface (I/F) unit 1013 for communicating with an external computer or the like. Furthermore, the photoelectric conversion system includes a recording medium 1012 such as a semiconductor memory for recording or reading out captured image data and a recording medium control I/F unit 1011 for recording data in or reading out data from the recording medium 1012. Note that the recording medium 1012 may be built in or detachable from the photoelectric conversion system.

Furthermore, the photoelectric conversion system includes a central control-operation unit 1009, which controls various types of arithmetic operations and the entire digital still camera, and a timing generation unit 1008, which outputs various types of timing signals to the image pickup apparatus 1004 and the signal processing unit 1007. In this case, a timing signal and the like may be input from the outside. It is sufficient that the photoelectric conversion system include at least the image pickup apparatus 1004 and the signal processing unit 1007, which processes an output signal output from the image pickup apparatus 1004.

The image pickup apparatus 1004 outputs an image pickup signal to the signal processing unit 1007. The signal processing unit 1007 performs certain signal processing on the image pickup signal output from the image pickup apparatus 1004 to output image data. The signal processing unit 1007 generates an image using the image pickup signal output from the image pickup apparatus 1004.

In this manner, according to the present embodiment, the photoelectric conversion system can be realized to which any one of the photoelectric conversion apparatuses (image pickup apparatuses) according to the embodiments described above.

### Tenth Embodiment

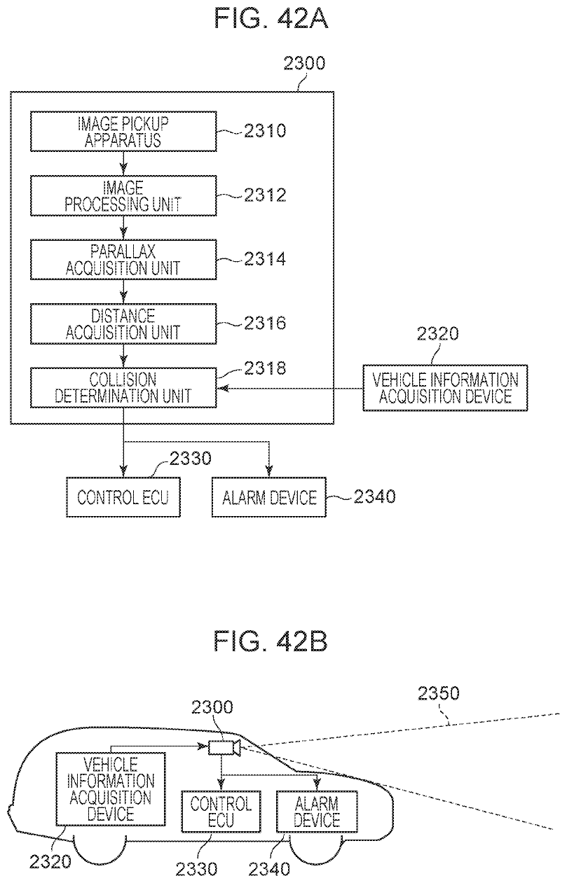

A photoelectric conversion system and a moving object according to the present embodiment will be described using FIGS. 42A and 42B. FIGS. 42A and 42B are diagrams illustrating the configurations of the photoelectric conversion system and the moving object according to the present embodiment.

FIG. 42A illustrates an example of the photoelectric conversion system regarding a vehicle-mounted camera. A photoelectric conversion system 2300 has an image pickup apparatus 2310. The image pickup apparatus 2310 is any one of the photoelectric conversion apparatuses described in the above-described embodiments. The photoelectric conversion system 2300 has an image processing unit 2312, which performs image processing on a plurality of pieces of image data acquired by the image pickup apparatus 2310. The photoelectric conversion system 2300 also has a parallax acquisition unit 2314, which calculates parallax (a phase difference of a parallax image) from a plurality of pieces of image data acquired by the image processing unit 2312. Furthermore, the photoelectric conversion system 2300 has a distance acquisition unit 2316 and a collision determination unit 2318. The distance acquisition unit 2316 calculates the distance to a target object on the basis of the calculated parallax. The collision determination unit 2318 determines on the basis of the calculated distance whether there are chances of a collision. In this case, the parallax acquisition unit 2314 or the distance acquisition unit 2316 is an example of a distance information acquisition unit configured to acquire information regarding the distance to the target object (hereinafter referred to as distance information). That is, the distance information is information regarding parallax, the amount of defocusing, the distance to the target object, and so forth. The collision determination unit 2318 may determine chances of a collision using any information included in the distance information. The distance information acquisition unit may be realized by a hardware device designed in a dedicated manner or a software module.

The distance information acquisition unit may also be realized by, for example, a field-programmable gate array (FPGA) or an application-specific integrated circuit (ASIC) or may also be realized by a combination of an FPGA and an ASIC.

The photoelectric conversion system 2300 is connected to a vehicle information acquisition device 2320 and can acquire vehicle information such as a vehicle speed, a yaw rate, and a steering angle. Moreover, a control engine control unit (ECU) 2330 is connected to the photoelectric conversion system 2300. The control ECU 2330 is a controller that outputs, on the basis of a determination result from the collision determination unit 2318, a control signal for causing the vehicle to generate a braking force. Moreover, the photoelectric conversion system 2300 is also connected to an alarm device 2340, which alerts the driver on the basis of a determination result from the collision determination unit 2318. For example, in a case where the chances of a collision are high based on a determination result from the collision determination unit 2318, the control ECU 2330 performs vehicle control to avoid a collision or reduce damage by braking, releasing the accelerator, controlling the engine output, or the like. The alarm device 2340 alerts the user by going off an alarm such as certain sound, displaying alarm information on the screen of, for example, a car navigation system, or vibrating their seat belt or the steering wheel.

In the present embodiment, images around the vehicle, for example, images of views in front of or behind the vehicle are captured by the photoelectric conversion system 2300. FIG. 42B illustrates the photoelectric conversion system for a case where images of views in front of the vehicle (an image pickup area 2350) are captured. The vehicle information acquisition device 2320 sends a command to the photoelectric conversion system 2300 or the image pickup apparatus 2310. With such a configuration, the accuracy of distance measurement can be more greatly improved.

In the above, an example has been described in which control for preventing the vehicle from colliding with other vehicles. However, the photoelectric conversion system 2300 can also be applied to perform, for example, control under which the vehicle drives autonomously so as to follow other vehicles or control under which the vehicle drives autonomously so as not to drive out of the lane. Furthermore, the photoelectric conversion system 2300 can be applied not only to vehicles such as cars but also to, for example, moving objects (moving apparatuses) such as vessels, airplanes, or industrial robots. In addition, the photoelectric conversion system 2300 can be applied not only to moving objects but also to a wide range of apparatuses using object recognition such as an intelligent transportation system (ITS).

### Eleventh Embodiment

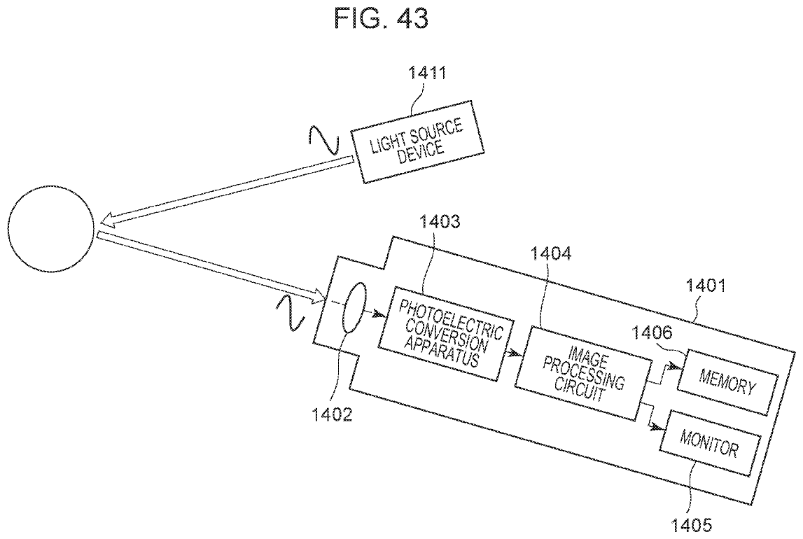

A photoelectric conversion system according to the present embodiment will be described using FIG. 43. FIG. 43 is a block diagram illustrating an example of the configuration of a distance image sensor, which is a photoelectric conversion system

As illustrated in FIG. 43, a distance image sensor 1401 includes an optical system 1402, a photoelectric conversion apparatus 1403, an image processing circuit 1404, a monitor 1405, and a memory 1406. The distance image sensor 1401 receives light emitted from a light source device 1411 to a subject and reflected by the surface of the subject (modulated light or pulsed light) and consequently can acquire a distance image corresponding to the distance to the subject.

The optical system 1402 includes one or more lenses. The optical system 1402 guides image light (incident light) from the subject to the photoelectric conversion apparatus 1403, and causes an image to be formed on a light receiving surface (a sensor unit) of the photoelectric conversion apparatus 1403.

As the photoelectric conversion apparatus 1403, any one of the photoelectric conversion apparatuses described in the individual embodiments described above is used. A distance signal representing a distance obtained from a light reception signal and output from the photoelectric conversion apparatus 1403 is supplied to the image processing circuit 1404.

The image processing circuit 1404 performs image processing in which a distance image is constructed on the basis of the distance signal supplied from the photoelectric conversion apparatus 1403. The distance image (image data) obtained as a result of the image processing is supplied to and displayed on the monitor 1405 or is supplied to and stored (recorded) in the memory 1406.

In the distance image sensor 1401 configured in this manner, the characteristics of pixels are improved by using one of the photoelectric conversion apparatuses described above and consequently, for example, a more accurate distance image can be acquired.

### Twelfth Embodiment

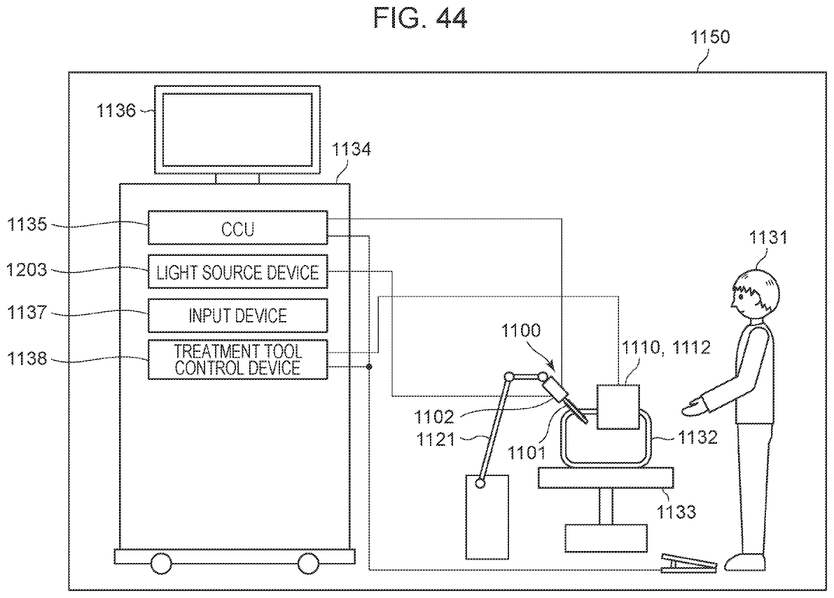

A photoelectric conversion system according to the present embodiment will be described using FIG. 44. FIG. 44 is a diagram illustrating an example of a schematic configuration of an endoscopic operation system, which is a photoelectric conversion system according to the present embodiment.

FIG. 44 illustrates a situation in which a practitioner (a doctor) 1131 is performing a surgical operation on a patient 1132 on a patient bed 1133 by using an endoscopic operation system 1150. As illustrated in FIG. 44, the endoscopic operation system 1150 includes an endoscope 1100, a surgical tool 1110, and a cart 1134, on which various types of devices for endoscopic operations are mounted.

The endoscope 1100 includes a lens tube 1101 and a camera head 1102. A portion of the lens tube 1101 starting from its leading edge and having a predetermined length is inserted into a body cavity of the patient 1132. The camera head 1102 is connected to a base end of the lens tube 1101. In the illustrated example, the endoscope 1100 is formed as a rigid scope including the lens tube 1101, which is rigid; however, the endoscope 1100 may be formed as a so-called flexible scope having a flexible lens tube.

The leading edge of the lens tube 1101 is provided with an opening in which an objective lens is embedded. The endoscope 1100 is connected to a light source device 1203. Light generated by the light source device 1203 is guided to the leading edge of the lens tube 1101 along a light guide extended in the lens tube 1101. Light guided to the leading edge of the lens tube 1101 is emitted toward an observation target in the body cavity of the patient 1132 through the objective lens. Note that the endoscope 1100 may be a direct-viewing endoscope, an oblique-viewing endoscope, or a side-viewing endoscope.

The camera head 1102 includes an optical system and a photoelectric conversion apparatus. Reflected light (observation light) from the observation target is concentrated by the optical system onto the photoelectric conversion apparatus. The observation light is photoelectrically converted by the photoelectric conversion apparatus, and an electric signal corresponding to the observation light, that is, an image signal corresponding to an observation image is generated. As the photoelectric conversion apparatus, any one of the photoelectric conversion apparatuses described in the individual embodiments described above can be used. The image signal is transmitted as RAW data to a camera control unit (CCU) 1135.

The CCU 1135 includes, for example, a central processing unit (CPU) and a graphics processing unit (GPU), and performs central control on operations of the endoscope 1100 and a display device 1136. Furthermore, the CCU 1135 receives an image signal from the camera head 1102, and performs, on the image signal, various types of image processing for displaying an image based on the image signal such as development processing (demosaicing) or the like.

The display device 1136 displays, under control performed by the CCU 1135, the image based on the image signal on which image processing is performed by the CCU 1135.

The light source device 1203 includes, for example, a light source such as a light-emitting diode (LED) and supplies, to the endoscope 1100, illumination light to be used when an image of a surgical target or the like is captured.

An input device 1137 is an input interface for the endoscopic operation system 1150. The user can input various types of information or commands to the endoscopic operation system 1150 through the input device 1137.

A treatment tool control device 1138 controls driving of an energy treatment tool 1112 for ablating or dissecting tissue, closing a blood vessel, or the like.

The light source device 1203 supplies, to the endoscope 1100, illumination light to be used when an image of a surgical target is captured. The light source device 1203 includes a white light source formed by, for example, LEDs, laser light sources, or a combination of LEDs and laser light sources. In a case where the white light source is formed by a combination of RGB laser light sources, the output intensity and the output timing of each color (each wavelength) can be controlled with high accuracy, and thus the white balance of a captured image can be adjusted by the light source device 1203. Moreover, in this case, by irradiating an observation target with laser light from each of the RGB laser light sources in a time division manner and controlling driving of an image sensor of the camera head 1102 in synchronization with the irradiation timing, images corresponding to R, G, and B in a respective manner can be captured in a time division manner. With the method, the image sensor can capture color images without being provided with color filters.

Driving of the light source device 1203 may be controlled such that the intensity of output light is changed every certain time period. Images are acquired in a time division manner by controlling driving of the image sensor of the camera head 1102 in synchronization with the timing at which the intensity of the light is changed, and the images are combined. As a result, high dynamic range images without so-called crushed shadows and blown highlights can be generated.

The light source device 1203 may also be configured to be able to supply light having a predetermined wavelength band corresponding to special light observation. In special light observation, for example, the wavelength dependence of light absorption in body tissue is used. Specifically, by performing irradiation with light of a narrower band than the illumination light used at the time of a normal observation (that is, white light), images of certain tissue such as a blood vessel in a mucosal surface layer can be captured with high contrast.

Alternatively, in special light observation, fluorescence observation may be performed in which an image is obtained using fluorescence generated by excitation light irradiation. In fluorescence observation, for example, body tissue is irradiated with excitation light, and fluorescence from the body tissue can be observed. Alternatively, in fluorescence observation, a reagent such as indocyanine green (ICG) is locally injected to body tissue, and the body tissue is irradiated with excitation light corresponding to the fluorescence wavelength of the reagent, so that a fluorescence image can be obtained. The light source device 1203 may be configured to be able to supply at least one out of light of a narrow band and excitation light that correspond to such special light observation.

### Thirteenth Embodiment

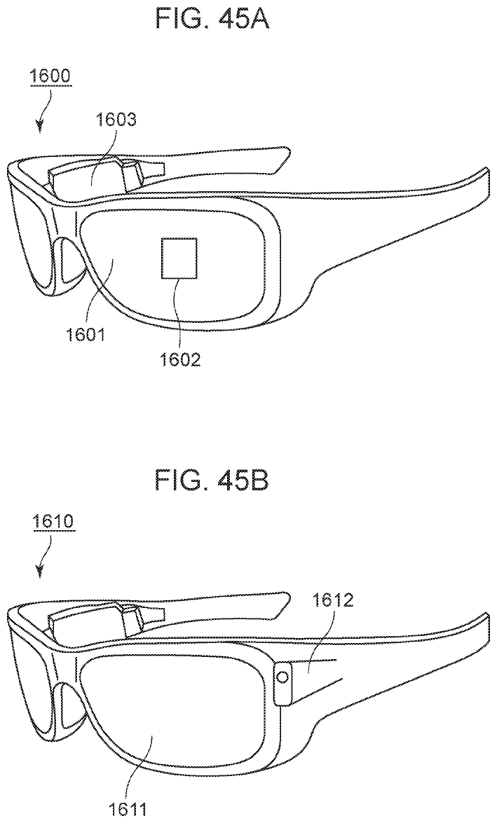

A photoelectric conversion system according to the present embodiment will be described using FIGS. 45A and 45B. FIG. 45A illustrates glasses 1600 (smart glasses), which constitute a photoelectric conversion system. The glasses 1600 have a photoelectric conversion apparatus 1602. The photoelectric conversion apparatus 1602 is one of the photoelectric conversion apparatuses described in the individual embodiments described above. A display device including a luminescent device such as an organic light-emitting diode (OLED) or a light-emitting diode (LED) may be provided on the back side of a lens 1601. There may be one photoelectric conversion apparatus 1602 or more. Alternatively, a plurality of types of photoelectric conversion apparatuses may be combined and used. The photoelectric conversion apparatus 1602 does not have to be arranged at the position illustrated in FIG. 45A.

The glasses 1600 further have a control device 1603. The control device 1603 functions as a power source that supplies power to the photoelectric conversion apparatus 1602 and the display device described above. The control device 1603 controls the operation of the photoelectric conversion apparatus 1602 and the display device. In the lens 1601, an optical system is formed that concentrate light onto the photoelectric conversion apparatus 1602.

FIG. 45B illustrates glasses 1610 (smart glasses) according to one application. The glasses 1610 have a control device 1612. The control device 1612 includes a photoelectric conversion apparatus corresponding to the photoelectric conversion apparatus 1602 and a display device. In a lens 1611, an optical system is formed that projects light emitted from the photoelectric conversion apparatus and the display device included in the control device 1612. An image is projected onto the lens 1611. The control device 1612 functions as a power source that supplies power to the photoelectric conversion apparatus and the display device, and controls the operation of the photoelectric conversion apparatus and the display device. The control device 1612 may have a line-of-sight detection unit configured to detect the line of sight of the wearer. Infrared rays may be used to detect the line of sight of the wearer. An infrared-emitting unit emits infrared light to an eyeball of the user gazing at a displayed image. An image of their eyeball is captured by an image capturing unit, which has a light reception element, detecting reflected light of the emitted infrared light from their eyeball. A decrease in the quality of images is reduced by provision of a reduction unit that reduces the amount of light from the infrared-emitting unit to a display unit in a plan view.

The line of sight of the user to the displayed image is detected from the image of their eyeball captured through image capturing using infrared light. A freely chosen known method can be applied to line-of-sight detection using a captured image of their eyeball. As an example, a line-of-sight detection method based on Purkinje images generated by reflected illumination light from the user's cornea can be used.

More specifically, line-of-sight detection processing based on a pupil-corneal reflection method is performed. The line of sight of the user is detected by calculating, using a pupil-corneal reflection method, a line-of-sight vector representing the orientation of their eyeball (a rotation angle) on the basis of an image of their pupil and Purkinje images included in a captured image of their eyeball.

The display device according to the present embodiment has a photoelectric conversion apparatus having a light reception element, and may control an image displayed on the display device on the basis of information regarding the user's line of sight from the photoelectric conversion apparatus.

Specifically, for the display device, a first line-of-sight region, at which the user gazes, and a second line-of-sight region other than the first line-of-sight region are determined on the basis of the line-of-sight information. The first line-of-sight region and the second line-of-sight region may be determined by the control device of the display device. Alternatively, the first line-of-sight region and the second line-of-sight region determined by an external control device may be received. In a display region of the display device, the display resolution of the first line-of-sight region may be controlled to be higher than that of the second line-of-sight region. That is, the resolution of the second line-of-sight region may be made lower than that of the first line-of-sight region.

The display region has a first display region and a second display region, which is different from the first display region. A prioritized region may be determined from among the first display region and the second display region on the basis of the line-of-sight information. The first display region and the second display region may be determined by the control device of the display device. Alternatively, the first display region and the second display region determined by an external control device may be received. The resolution of the prioritized region may be controlled to be higher than that of the region other than the prioritized region. That is, the resolution of the region having a relatively low priority may be reduced.

Note that artificial intelligence (AI) may be used to determine the first line-of-sight region or the prioritized region. AI may be a model configured to use an image of a user's eyeball and the direction in which their eyeball in the image actually sees as supervised data and to estimate the angle of the line of sight from an image of a user's eyeball and the distance to a target ahead of the line of sight. The display device, the photoelectric conversion apparatus, or an external device may have an AI program. In a case where an external device has the AI program, the angle of the line of sight of the user and the distance to the target are transferred to the display device through communication.

In a case where display control is performed on the basis of visual recognition and detection, the present embodiment can be applied to smart glasses further having a photoelectric conversion apparatus that captures an outside image. The smart glasses can display, in real time, outside information regarding a captured outside image.

### MODIFIED EMBODIMENTS

The present disclosure is not limited to the embodiments described above, and various modifications are possible.

For example, an example obtained by adding part of any one of the embodiments to another one of the embodiments and an example obtained by replacing part of one of the embodiments with part of another one of the embodiments are also included in embodiments of the present disclosure.

Furthermore, the photoelectric conversion systems described in the ninth and tenth embodiments are examples of photoelectric conversion systems to which the photoelectric conversion apparatuses can be applied. The photoelectric conversion systems to which the photoelectric conversion apparatuses according to the present disclosure are applicable are not limited to the configurations illustrated in FIGS. 41 to 42B.

The same applies to the ToF system described in the eleventh embodiment, the endoscope described in the twelfth embodiment, and the smart glasses described in the thirteenth embodiment.

Note that the embodiments described above are merely specific examples of embodiments for implementing the present disclosure, and the technical scope of the present disclosure should not be interpreted as limited by these embodiments. In other words, the present disclosure can be implemented in various forms without departing from its technical concept or its main features.

According to the disclosure of the present application, the performance of a photoelectric conversion apparatus can be improved by arranging a through-region and a through-via in a certain manner as described in the embodiments.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-190036, filed Nov. 29, 2022, and Japanese Patent Application No. 2023-186022, filed Oct. 30, 2023, which are hereby incorporated by reference herein in their entirety.

What is claimed is:

1. A photoelectric conversion apparatus comprising:
a first component including a first substrate and a first wiring layer, the first substrate having a first plane and a second plane facing the first plane and having a pixel region in which a plurality of avalanche photodiodes are arranged, the first wiring layer being provided on a side where the first plane of the first substrate is provided; and
a second component including a second substrate, a quenching device, and a second wiring layer, the second substrate having a third plane and a fourth plane facing the third plane, the second wiring layer being provided on a side where the third plane of the second substrate is provided, wherein
the second substrate has an insulating region, and the insulating region has a through-electrode provided in a through-region that penetrates through the second substrate,
the quenching device is separated from another element by the insulating region, and
the first component and the second component are electrically connected to each other in a region that overlaps the pixel region in a plan view.

2. The photoelectric conversion apparatus according to claim 1, wherein only the insulating region is arranged between the quenching device and the through-electrode.

3. The photoelectric conversion apparatus according to claim 1, wherein the second component includes a waveform shaping unit, and
the insulating region is arranged between the waveform shaping unit and the quenching device.

4. The photoelectric conversion apparatus according to claim 1, wherein the second component includes a signal processing circuit, and
the insulating region is arranged between the signal processing circuit and the quenching device.

5. The photoelectric conversion apparatus according to claim 1, wherein a sidewall of the through-region is oxidized.

6. The photoelectric conversion apparatus according to claim 1, wherein the through-electrode and the quenching device are connected to a wiring line closest to the second substrate among wiring lines included in the second wiring layer.

7. The photoelectric conversion apparatus according to claim 1, wherein the through-electrode and the quenching device are connected to a polysilicon wiring line provided in the second substrate.

8. The photoelectric conversion apparatus according to claim 1, wherein an opening of the through-region formed in the third plane is larger than an opening of the through-region formed in the fourth plane.

9. The photoelectric conversion apparatus according to claim 1, wherein the insulating region has a stepped shape.

10. The photoelectric conversion apparatus according to claim 1, wherein a thickness of a gate oxide film of a first element arranged in the first substrate is different from a thickness of a gate oxide film of a second element arranged in the second substrate.

11. The photoelectric conversion apparatus according to claim 10, wherein the first element and the second element are arranged so as to face each other with the through-region interposed therebetween.

12. The photoelectric conversion apparatus according to claim 1, wherein part of the insulating region does not penetrate through the second substrate.

13. The photoelectric conversion apparatus according to claim 1, wherein the through-electrode is connected to the first substrate.

14. The photoelectric conversion apparatus according to claim 1, wherein a first voltage and a second voltage are applied to the avalanche photodiodes, and
an electrode for supplying the first voltage from outside is formed on a side where the second plane is provided.

15. The photoelectric conversion apparatus according to claim 1, further comprising: a third component including a third substrate and a third wiring layer, the third substrate having a fifth plane and a sixth plane facing the fifth plane, the third wiring layer being provided on a side where the fifth plane of the third substrate is provided, wherein
the first plane of the first component and the fourth plane of the second component are bonded together, and
the third plane of the second component and the fifth plane of the third component are bonded together.

16. The photoelectric conversion apparatus according to claim 1, further comprising: a third component including a third substrate and a third wiring layer, the third substrate having a fifth plane and a sixth plane facing the fifth plane, the third wiring layer being provided on a side where the fifth plane of the third substrate is provided, wherein
the first plane of the first component and the third plane of the second component are bonded together, and
the fourth plane of the second component and the sixth plane of the third component are bonded together.

17. The photoelectric conversion apparatus according to claim 1, further comprising: a third component including a third substrate and a third wiring layer, the third substrate having a fifth plane and a sixth plane facing the fifth plane, the third wiring layer being provided on a side where the fifth plane of the third substrate is provided, wherein
the first plane of the first component and the fourth plane of the second component are bonded together, and
the third plane of the second component and the sixth plane of the third component are bonded together.

18. A photoelectric conversion system comprising:
a photoelectric conversion apparatus including:
a first component including a first substrate and a first wiring layer, the first substrate having a first plane and a second plane facing the first plane and having a pixel region in which a plurality of avalanche photodiodes are arranged, the first wiring layer being provided on a side where the first plane of the first substrate is provided; and
a second component including a second substrate, a quenching device, and a second wiring layer, the second substrate having a third plane and a fourth plane facing the third plane, the second wiring layer being provided on a side where the third plane of the second substrate is provided, wherein
the second substrate has an insulating region, and the insulating region has a through-electrode provided in a through-region that penetrates through the second substrate,
the quenching device is separated from another element by the insulating region,
the first component and the second component are electrically connected to each other in a region that overlaps the pixel region in a plan view; and
a signal processing unit configured to generate an image using a signal output by the photoelectric conversion apparatus.

19. A moving object comprising:
a photoelectric conversion apparatus including:
a first component including a first substrate and a first wiring layer, the first substrate having a first plane and a second plane facing the first plane and having a pixel region in which a plurality of avalanche photodiodes are arranged, the first wiring layer being provided on a side where the first plane of the first substrate is provided; and
a second component including a second substrate, a quenching device, and a second wiring layer, the second substrate having a third plane and a fourth plane facing the third plane, the second wiring layer being provided on a side where the third plane of the second substrate is provided, wherein
the second substrate has an insulating region, and the insulating region has a through-electrode provided in a through-region that penetrates through the second substrate,
the quenching device is separated from another element by the insulating region,
the first component and the second component are electrically connected to each other in a region that overlaps the pixel region in a plan view; and
a controller configured to control movement of the moving object using a signal output by the photoelectric conversion apparatus.
